(19) United States
(12) Patent Application Publication
(10) Pub. No.: US 2025/0006639 A1
(43) Pub. Date: Jan. 2, 2025

(54) SEMICONDUCTOR STRUCTURE AND MANUFACTURING METHOD THEREOF

(71) Applicants: TAIWAN SEMICONDUCTOR MANUFACTURING COMPANY, LTD., Hsinchu (TW); NATIONAL TAIWAN UNIVERSITY, Taipei (TW)

(72) Inventors: Chi-Yuan KUO, New Taipei City (TW); Jia-Heng ZHU, Chiayi County (TW); I-Chih NI, New Taipei City (TW); Chih-I WU, Taipei City (TW)

(73) Assignees: TAIWAN SEMICONDUCTOR MANUFACTURING COMPANY, LTD., Hsinchu (TW); NATIONAL TAIWAN UNIVERSITY, Taipei (TW)

(21) Appl. No.: 18/346,230

(22) Filed: Jul. 1, 2023

(51) Int. Cl. H01L 23/532; H01L 21/768

(52) U.S. Cl. CPC H01L 23/53276; H01L 21/76843; H01L 23/53209; H01L 23/53223; H01L 23/53238; H01L 23/53252; H01L 23/53266

(57) ABSTRACT

A method includes loading a wafer having a dielectric layer thereon into a processing chamber; introducing a hydrocarbon precursor into the processing chamber; pyrolyzing the hydrocarbon precursor; introducing the pyrolyzed hydrocarbon precursor to the dielectric layer to form a graphene layer on the dielectric layer at a temperature lower than about 400° C.

### BACKGROUND

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flowchart of a method for forming a semiconductor structure in accordance with some embodiments of the present disclosure.

FIGS. 2, 3A-5C, 6 and 7A illustrate a method in various stages of forming a semiconductor structure including a graphene layer in accordance with some embodiments of the present disclosure.

FIGS. 5D and 5E illustrate experimental results of a Raman spectrum of graphene formed on a dielectric layer.

FIG. 7B illustrates a method of performing time dependent dielectric breakdown (TDDB) measurement on a semiconductor structure with a graphene as the barrier in accordance with some embodiments of the present disclosure.

FIGS. 7C-7E are time dependent dielectric breakdown (TDDB) measurement results of semiconductor structures with and without graphene as the barriers in accordance with some embodiments of the present disclosure.

FIGS. 8A-8L illustrate a method in various stages of forming a semiconductor device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” may mean within 20 percent, or within 10 percent, or within 5 percent of a given value or range. One skilled in the art will realize, however, that the value or range recited throughout the description are merely examples, and may be reduced with the down-scaling of the integrated circuits. Numerical quantities given herein are approximate, meaning that the term “around,” “about,” “approximately,” or “substantially” can be inferred if not expressly stated.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

In the back end of line (BEOL) process in the semiconductor structure, interconnects are fabricated to electrically link transistors and other components on a semiconductor device. These interconnects are typically made of metal lines, such as copper, tungsten, or other suitable materials, which can suffer from electromigration and diffusion issues that can lead to device failure. Graphene serving as a barrier layer on the metal lines can make it a candidate for addressing these issues. However, the current methods for depositing graphene on dielectric materials often involve high temperatures or plasma-enhanced processes, which can cause damage to the dielectric materials due to plasma ion bombardment.

Therefore, the present disclosure in various embodiments provides a method of forming graphene on dielectric materials at temperatures below 400 degrees Celsius. Other embodiments and variations are possible within the scope of the disclosure, as will be apparent to those skilled in the art. Specifically, a hot wire-chemical vapor deposition (HW-CVD) process is provided to perform a pyrolyzation on a carbon precursor. Subsequently, the pyrolyzed carbon precursor can be introduced to a dielectric material at a temperature lower than about 400° C. to form a graphene layer on the dielectric material, and the dielectric material is where the interconnects will be formed subsequently. In some embodiments, ammonia (NH₃) is introduced near the surface of the dielectric materials to react with the unpyrolyzed hydrocarbon precursors. This reaction ensures that the environment near the surface of the dielectric materials remains saturated with carbon, promoting the adsorption of carbon atoms onto the surface. After achieving the desired carbon atom coverage on the dielectric surface, the temperature on the dielectric materials decrease induces the adsorbed carbon atoms to arrange themselves into a two-dimensional honeycomb lattice structure, crystallizing into graphene on the surface of the dielectric materials.

This method enables the growth of graphene on dielectric materials at temperatures below 400 degrees Celsius, making it compatible with semiconductor BEOL processes and reducing the risk of thermal damage to the underlying structures. Unlike plasma-enhanced processes, this method does not involve plasma ion bombardment, minimizing the potential for damage to the dielectric material substrate and ensuring the integrity of the underlying structures. By controlling the reaction conditions and introducing specific gases, the method allows for the growth of high-quality graphene layers on dielectric materials, which can improve the performance of semiconductor devices in BEOL processes.

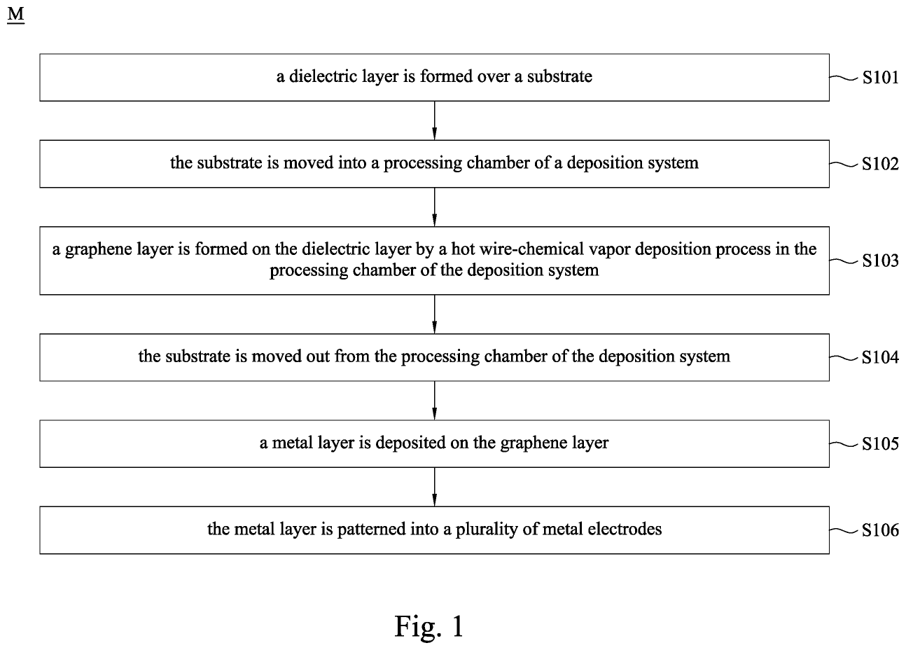

Referring now to FIG. 1, illustrated is a flowchart of an exemplary method M for fabrication of a semiconductor structure 100 in accordance with some embodiments. The method M includes a relevant part of the entire manufacturing process. It is understood that additional operations may be provided before, during, and after the operations shown by FIG. 1, and some of the operations described below can be replaced or eliminated for additional embodiments of the method. The order of the operations/processes may be interchangeable. The method M includes fabrication of the semiconductor structure 100. However, the fabrication of the semiconductor structure is merely an example for describing the manufacturing process according to some embodiments of the present disclosure.

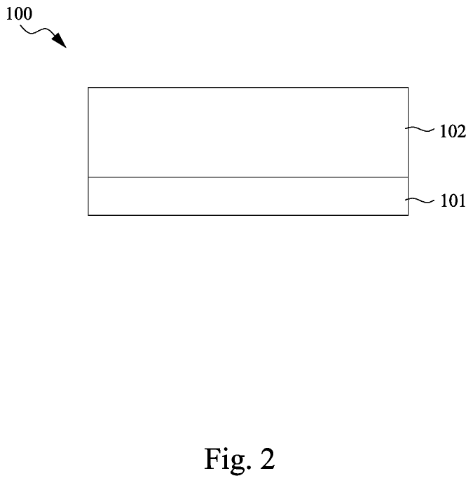

Reference is made to FIGS. 2, 3A-5B, 6 and 7A. FIGS. 2, 3A-5B, 6 and 7A illustrate a method in various stages of forming the semiconductor structure 100 including a graphene layer formed on a dielectric layer in accordance with some embodiments of the present disclosure.

The method M begins at block S101 where a dielectric layer is formed over a substrate. Referring to FIG. 2, in some embodiments of block S101, a substrate 101 is provided. The substrate 101 may be a semiconductor substrate, such as a bulk semiconductor, a semiconductor-on-insulator (SOI) substrate, or the like, which may be doped (e.g., with a p-type or an n-type impurity) or undoped. The substrate 101 may be a wafer, such as a silicon wafer. Generally, a SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 101 may include silicon; germanium; a compound semiconductor including silicon carbide, gallium arsenide, gallium phosphide, indium phosphide, indium arsenide, and/or indium antimonide; an alloy semiconductor including silicon germanium, gallium arsenide phosphide, aluminum indium arsenide, aluminum gallium arsenide, gallium indium arsenide, gallium indium phosphide, and/or gallium indium arsenide phosphide; combinations thereof; or the like.

Subsequently, a dielectric layer 102 is formed over the substrate 101. The dielectric layer 102 may be formed of a dielectric material, which may be deposited by any suitable method, such as CVD, plasma-enhanced CVD (PECVD), FCVD, or the like. Acceptable dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, the dielectric layer 102 may be formed of low-k dielectric materials. The dielectric constants (k values) of the low-k dielectric materials may be less than about 3.0, or less than about 2.5, for example. In some embodiments, the dielectric layer 102 may include multiple dielectric material and selected from a group including of SiO₂, Si₃N₄, carbon doped oxide, nitrogen doped oxide, porous oxide, air gap, or combinations thereof.

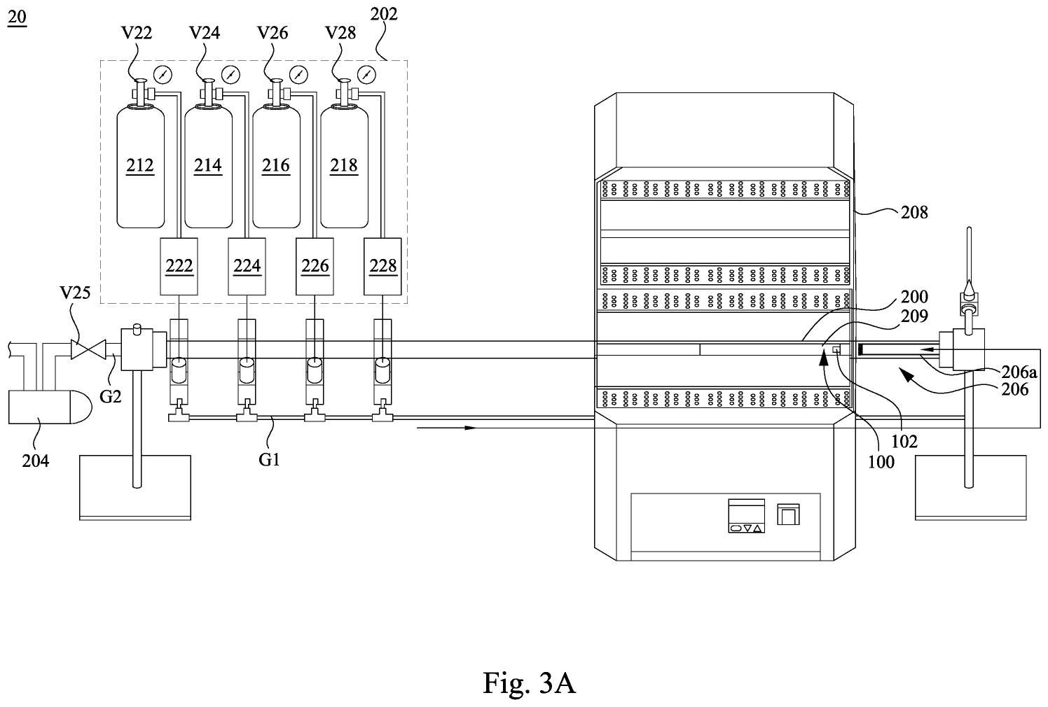

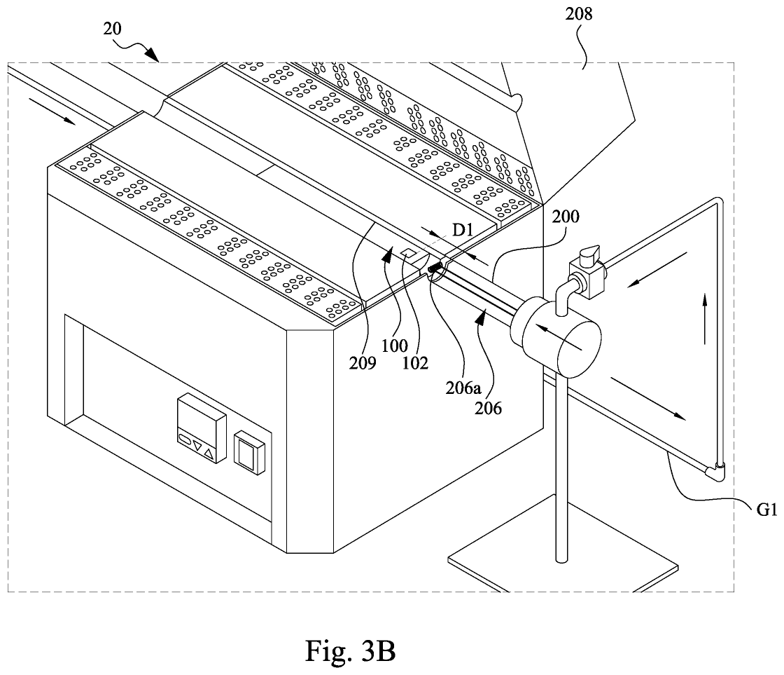

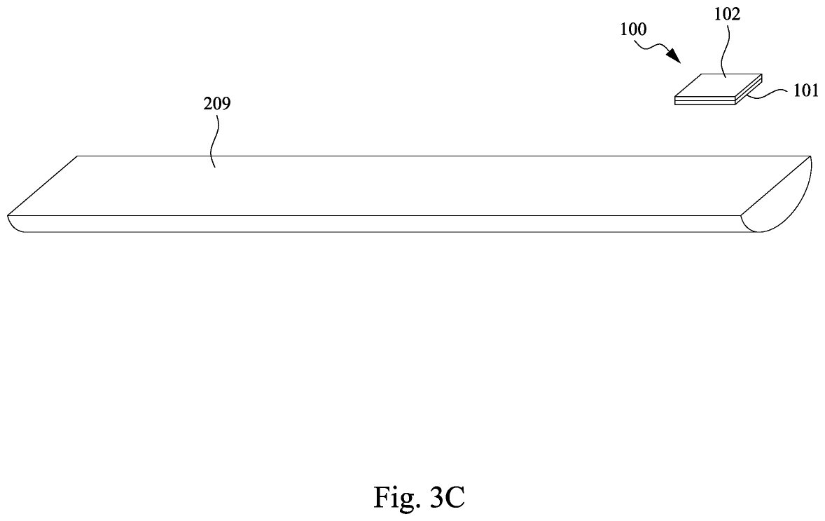

Referring back to FIG. 1, the method M then proceeds to block S102 where the substrate is moved into a processing chamber of a deposition system. With reference to FIGS. 3A-3C, in some embodiments of block S102, the substrate 101 is moved into a processing chamber 200 of a deposition system 20 and on a carrier 209. In some embodiments, the deposition system 20 can be served as a chemical vapor deposition (CVD) system. This is described in greater detail with reference to FIGS. 3A and 3B, which illustrate schematic perspective views of an exemplary deposition system 20 in some embodiments of the present disclosure. As shown in FIGS. 3A and 3B, the deposition system 20 includes a processing chamber 200, a gas delivery system 202, a vacuum pump 204, a heating belt 206 defining a separate heating region to pyrolyze a carbon precursor from the gas delivery system 202, a heater 208 (e.g., furnace) used to dissociate the carbon precursor (e.g., hydrocarbon precursor) on a dielectric layer 102. In some embodiments, the gas delivery system 202 is connected to the processing chamber 200 via a gas delivery line G1, and the vacuum pump 204 is connected to the processing chamber 200 via a gas delivery line G2. The heater 208 surrounds an exterior of a portion of the processing chamber 200 near the gas delivery line G2. The heating belt 206 is between the gas delivery line G1 and the heater 208.

In some embodiments of FIGS. 3A and 3B, the processing chamber 200 is an elongated tube extending laterally. By way of example but not limiting the present disclosure, the processing chamber 200 may be a quartz tube. In some embodiments, the gas delivery lines G1 and G2 are fluidly communicated with the processing chamber 200, in which the gas delivery lines G1 and G2 are fluidly communicated with opposite sides of the processing chamber 200. The processing chamber 200 can accommodate the substrate 101 having the dielectric layer 102 and the dielectric layer 102 thereon. In some embodiments, the heating belt 206 includes a filament 206a coupled to a portion of the processing chamber 200 near the gas delivery line G1. The filament 206a may be made of tantalum (Ta), or other suitable conductive materials. In some embodiments, the filament 206a can be a multiple turn cylindrical configuration wire that has about 3 to about 15 turns, such as about 3, 4, 5, 6, 7, 8, 9, 10, 11, 12, 13, 14, or 15, by way of example but not limiting the present disclosure. In some embodiments, the filament 206a may have a wire diameter in a range from about 0.1 mm to about 0.4 mm, such as about 0.1, 0.15, 0.2, 0.25, 0.3, 0.35, or 0.4 mm. In some embodiments, the filament 206a may have a turn diameter in a range from about 2 mm to about 4 mm, such as about 2, 2.2, 2.4, 2.6, 2.8, 3, 3.1, 3.2, 3.4, 3.6, 3.8, or 4 mm. In some embodiments, the filament 206a may have a length in a range from about 10 cm to about 30 cm, such as about 10, 12, 14, 16, 18, 20, 22, 24, 26, 28, or 30 cm.

The gas delivery system 202 will now be described. In some embodiments, the gas delivery system 202 includes several sources 212, 214, 216, and 218. In the example shown in FIG. 3A, four sources are illustrated, while more or less sources may be applied in some other embodiments. The gas delivery system 202 includes several mass flow controllers 222, 224, 226, and 228, in which the mass flow controllers 222, 224, 226, and 228 are connected to the sources 212, 214, 216, and 218 via valves V22, V24, V26, and V28, respectively. Moreover, the mass flow controllers 222, 224, 226, and 228 are connected to the gas delivery line G1 via valves V22, V24, V26, and V28 respectively. In some embodiments, the sources 212, 214, 216, and/or 218 is a liquid source, and thus the sources 212, 214, 216, and/or 218 may include a liquid tank. For example, the liquid of the source 212 may include liquid carbon-containing material. In some embodiments, the carbon elements of the carbon-containing material (e.g., methane, ethane, propane, ethene, propene, acetylene) are used as a source for depositing a graphene layer discussed below. On the other hand, the sources 214, 216, and 218 are gas sources, and thus the sources 214, 216, and 218 may include gas cylinders. The gases of the sources 214, 216, and 218 may be, for example, H₂, Ar, N₂, Cl₂, NH₃ or other suitable gases. The vacuum pump 204 is connected to the gas delivery line G2 via a valve V25. The remainder of the gas mixture exhausted from the processing chamber 200, including reaction products or byproducts, is evacuated from the processing chamber 200 by the vacuum pump 204.

Referring back to FIG. 1, the method M then proceeds to block S103 where a graphene layer is formed on the dielectric layer by a hot wire-chemical vapor deposition (HW-CVD) process in the processing chamber of the deposition system. Specifically, graphene is a one-atom-thick layer of carbon atoms arranged in a two-dimensional (2D) honeycomb lattice structure. It is a single layer of graphite and has physical, electrical, and mechanical properties that make it a material for various applications. Some of its properties include high electron mobility, high thermal conductivity, and excellent electrical conductivity. In the back end of line (BEOL) process in the semiconductor structure, interconnects are fabricated to electrically link transistors and other components on a semiconductor device. These interconnects are typically made of metal lines, such as copper, tungsten, or other suitable materials, which can suffer from electromigration and diffusion issues that can lead to device failure. The graphene's properties can make it a candidate for addressing these issues. For example, the graphene's tightly packed carbon atoms create a nearly impermeable barrier, preventing metal atoms from diffusing into adjacent dielectric layers. This helps maintain the integrity of the metal lines and prevents short-circuiting and other issues related to diffusion. In addition, the graphene is a conductor of electricity, allowing for efficient electron transport along the metal lines. This can help reduce resistance and improve the overall performance of the semiconductor device. Furthermore, the graphene's high thermal conductivity can effectively dissipate heat generated by the metal lines during operation. This can help prevent the formation of hotspots and improve the reliability and longevity of the semiconductor device. Therefore, the graphene may have the potential to serve as a barrier layer for metal lines in the BEOL process, improving device performance, reliability, and longevity.

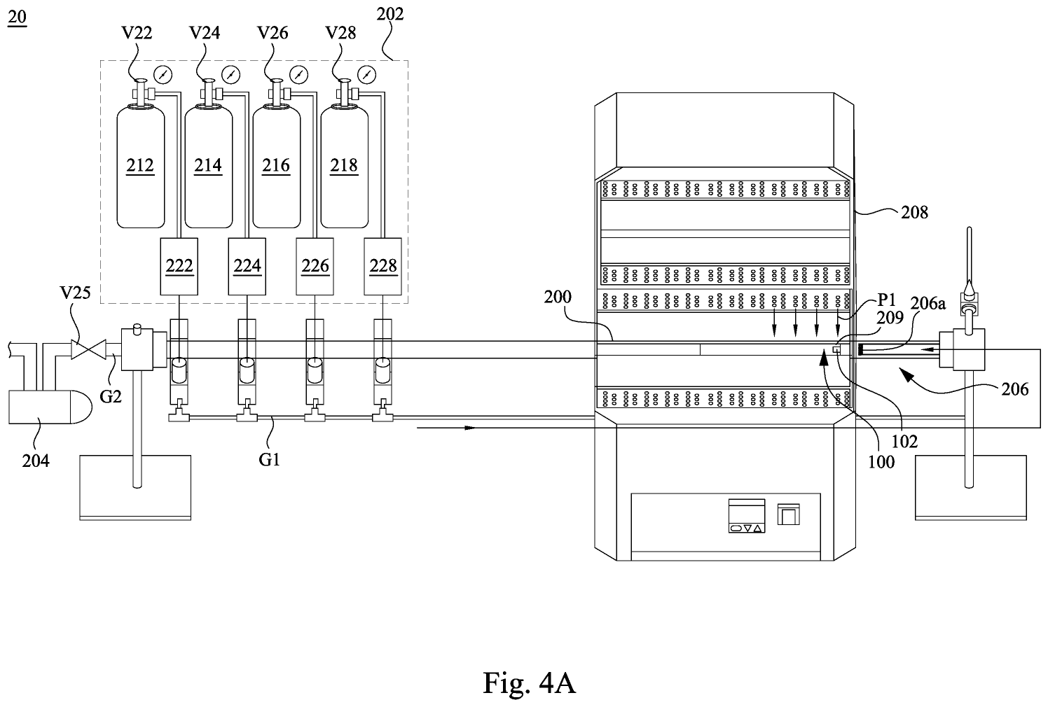

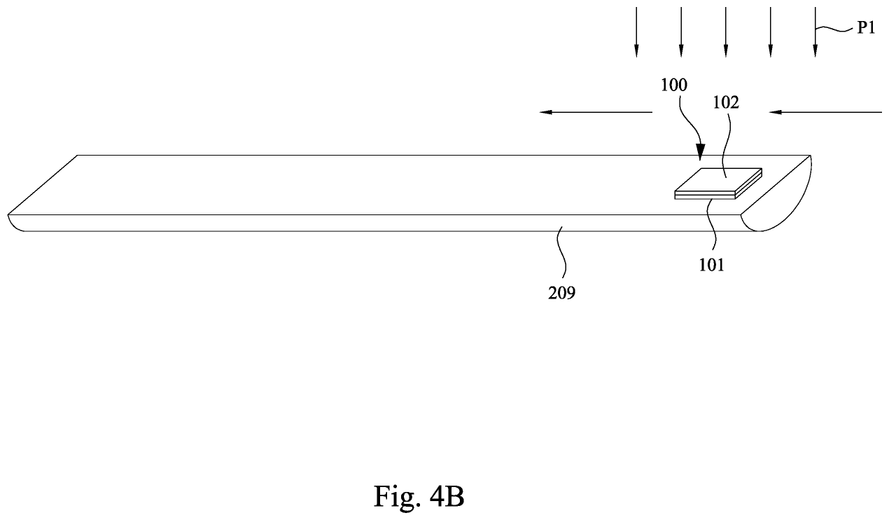

With reference to FIGS. 4A and 4B, in some embodiments of block S103, a HW-CVD process P1 is performed to form a graphene layer 104 on the dielectric layer 102. During the HW-CVD process P1, the dielectric layer 102 is exposed to an environment rich (e.g., processing chamber 200) in carbon. The high carbon concentration allows carbon atoms to adsorb onto the surface of the dielectric layer 102. In some embodiments, the dielectric layer 102 can be interchangeably referred to as a metal-free substrate.

Specifically, the substrate 101 and the dielectric layer 102 are heated to a predetermined temperature, such as about 300 to 400° C., through the heater 208 in an atmosphere with a carrier gas mixture including hydrogen (H₂), argon (Ar), and ammonia (NH₃). The carrier gas mixture is introduced into the processing chamber 200 from the sources 212, 214, and 218 through the gas delivery line G1. In some embodiments, the argon carrier gas may be performed with a flow rate in a range from between about 20 sccm to about 200 sccm, such as about 20, 25, 50, 75, 100, 125, 150, 175, or 200 sccm. In some embodiments, the hydrogen carrier gas may be performed with a flow rate in a range from between about 20 sccm to about 200 sccm, such as about 20, 25, 50, 75, 100, 125, 150, 175, or 200 sccm.

Subsequently, a carbon precursor in a gas state is introduced into the processing chamber 200 under a process pressure in a range from about 1 to about 20 Torr, such as about 1, 2, 3, 4, 5, 6, 7, 8, 9, 10, 11, 12, 13, 14, 15, 16, 17, 18, 19, or 20 Torr, from the source 212. The carbon precursor may include a carbon-containing material, such as methane, ethane, propane, ethene, propene, acetylene, other suitable material, or combinations thereof. In some embodiments, the carbon precursor may be performed with a flow rate in a range from between about 3 sccm to about 150 sccm, such as about 3, 10, 20, 30, 40, 50, 60, 70, 80, 90, 100, 110, 120, 130, 140, or 150 sccm. The carbon precursor is pyrolyzed by the filament 206a of the heating belt 206. The carbon precursor is cracked to broken the carbon precursor down into carbon atoms, by the breaking of carbon-carbon bonds and/or carbon-hydrogen bonds in the carbon precursor. In some embodiments, the filament 206a is performed to heat to a temperature that the carbon precursor can be pyrolyzed, the temperature can be in a range from about 2000 to 3000° C., such as about 2000, 2100, 2200, 2277, 2300, 2400, 2500, 2527, 2600, 2700, 2800, 2900, or 3000° C.

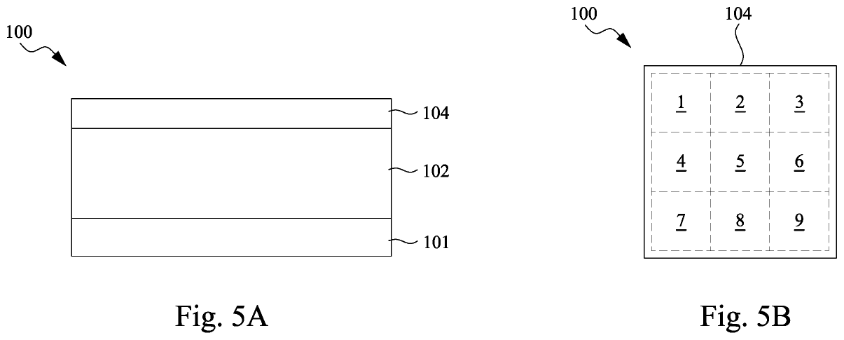

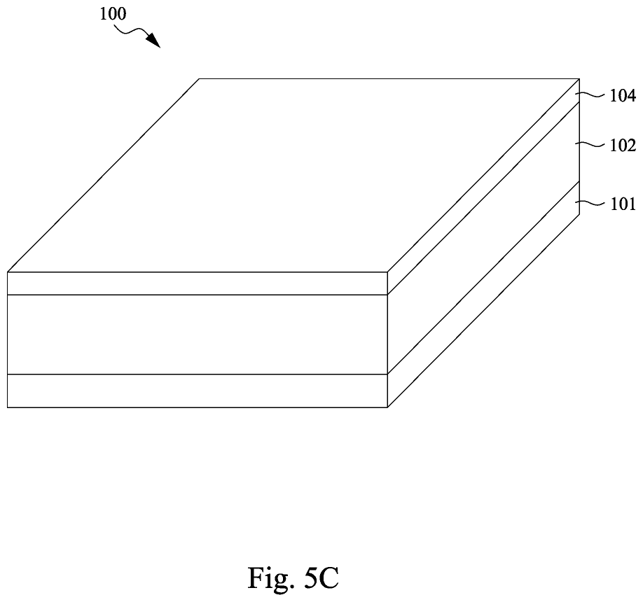

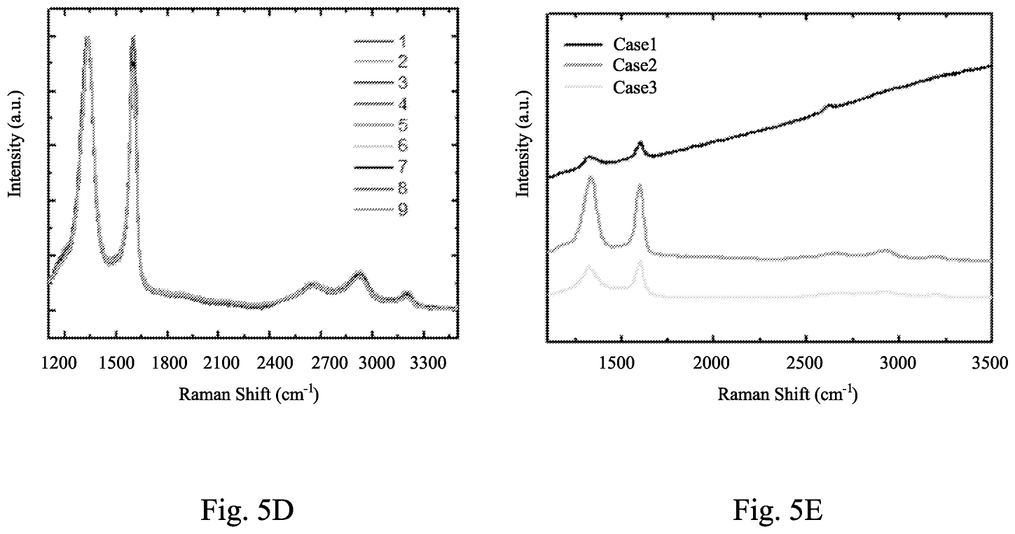

In some embodiments, the carbon rich environment is maintained for about 5 to about 30 minutes to allow the graphene layer 104 (see FIG. 5A) to grow on the dielectric layer 102. In addition, the temperature of the environment around the substrate 101 in the processing chamber 200 is controlled to maintain between about 300 and 400 degrees Celsius to prevent carbon atoms from rebonding or forming an amorphous state on the surface of the dielectric layer 102. When the temperature is between 300 and 400 degrees Celsius, the surface energy of the dielectric layer 102 increases due to the increased thermal energy. The increase in surface energy has the following effects, which can help carbon atoms to form graphene on the surface of the dielectric material. For example, with increased surface energy, the dielectric layer 102 becomes more reactive, which can promote the adsorption of carbon atoms on the surface. This ensures a sufficient density of carbon atoms necessary for the formation of a high-quality graphene layer. In addition, carbon atoms gain enough energy to move across the surface of the dielectric layer 102. This mobility allows carbon atoms to find energetically favorable positions and form the stable, two-dimensional honeycomb lattice structure characteristic of graphene. Furthermore, the increased surface energy also lowers the energy barrier for carbon atoms to rearrange themselves into the graphene lattice. This makes the formation of the graphene layer more thermodynamically favorable and ensures a well-ordered, high-quality graphene layer. This temperature induces the adsorbed carbon atoms to arrange themselves into a two-dimensional honeycomb lattice structure, crystallizing into graphene on the surface of the dielectric layer 102. By following this process and controlling the reaction conditions, such as temperature, gas flow rates, and catalyst presence, it is possible to grow high-quality graphene layers on the surface of dielectric layer 102, which can then be used in various applications. In some embodiments, the process temperature range can depend on the selected carbon source or inorganic source of material. For example, when methane is used, the temperature for graphene growth can be higher than when benzene is used. In some embodiments, pyrolyzing the carbon precursor includes providing a current in a range from about 4 to about 6 A, such as about 4, 4.5, 4.58, 5, 5.04, 5.5, or 6 A, on the filament 206a (see FIG. 4A).

In some embodiments, ammonia (NH₃) is introduced near the surface of the dielectric layer 102 to react with the unpyrolyzed hydrocarbon precursors. The reaction between ammonia and the hydrocarbon gas forms intermediate compounds, such as imines or amines, and releases carbon atoms near the surface of the dielectric material:

C₂H₂+2NH₃→C₂+2NH₄

This reaction ensures that the environment near the surface of the dielectric layer 102 remains saturated with carbon, promoting the adsorption of carbon atoms onto the surface. Further, when the temperature around the substrate 101 in the processing chamber 200 is between 300 and 400 degrees Celsius, the reaction kinetics between the ammonia (NH₃) and carbon precursor, ensuring that carbon atoms are continuously supplied to the dielectric surface. This further facilitates the formation of graphene by maintaining a carbon-saturated environment near the surface. In some embodiments, the flow rate of the ammonia precursor is less than about 0.1% of the flow rate of the carbon precursor. In some embodiments, the flow rate of the ammonia precursor is in a range from about 0.01% to 0.1% of the sum of the flow rates of all other carrier gases (e.g., the sum of the flow rates of argon carrier gas, hydrogen carrier gas, and carbon precursor). If the flow rate of the ammonia precursor is less than about 0.01% of the sum of the flow rates of all other carrier gases, there may not be enough ammonia available to facilitate the formation of graphene with the desired crystalline quality and uniformity. Low ammonia flow rates may not provide the saturated carbon concentration near the dielectric material's surface, leading to poor adsorption of carbon atoms and inferior graphene formation. If the flow rate of the ammonia precursor is greater than about 0.1% of the sum of the flow rates of all other carrier gases, excessive ammonia could be present, which may lead to unwanted side reactions or the formation of unwanted by-products. High ammonia flow rates can disrupt the optimal conditions for graphene formation, resulting in defects, non-uniformity, or decreased crystalline quality. By way of example but not limiting the present disclosure, the ammonia precursor may be performed with a flow rate in a range from between about 0.04 sccm to about 0.4 sccm, such as about 0.04, 0.08, 0.1, 0.15, 0.2, 0.25, 0.3, 0.35, or 0.4 sccm.

Specifically, the carbon precursor decomposes under the influence of heat or a catalyst, releasing carbon atoms that adsorb onto the dielectric material's surface. These carbon atoms then rearrange to form a single layer of graphene via a process called nucleation. To form multilayered graphene, the process is repeated to deposit additional graphene layers on top of the initial layer. This can be achieved by extending the deposition time, increasing the carbon precursor concentration, or adjusting other process parameters. The additional layers may grow through a process called epitaxial growth, where the subsequent graphene layers adopt the crystalline structure of the underlying layer. Once the desired number of graphene layers has been achieved, the carbon precursor flow is stopped, and the reaction chamber is cooled down to room temperature.

The present disclosure in various embodiments provides the HW-CVD process P1 performed the pyrolyzation on a carbon precursor in advance and without an additional transferring process after the formation of the graphene layer 104. Specifically, during the HW-CVD process P1, a carbon precursor is pyrolyzed with the filament 206a of the heating belt 206 in the processing chamber 200, and then introduced to the dielectric layer 102. In some embodiments, ammonia (NH₃) is introduced near the surface of the dielectric layer 102 to react with the unpyrolyzed hydrocarbon precursors. This reaction ensures that the environment near the surface of the dielectric layer 102 remains saturated with carbon, promoting the adsorption of carbon atoms onto the surface. After achieving the desired carbon atom coverage on the dielectric surface, the temperature on the dielectric layer 102 decrease induces the adsorbed carbon atoms to arrange themselves into a two-dimensional honeycomb lattice structure, crystallizing into graphene on the surface of the dielectric layer 102.

This method enables the growth of the graphene layer 104 on the dielectric layer 102 at temperatures below 400 degrees Celsius, making it compatible with semiconductor BEOL processes and reducing the risk of thermal damage to the underlying structures. Unlike plasma-enhanced processes, this method does not involve plasma ion bombardment, minimizing the potential for damage to the dielectric layer 102 and ensuring the integrity of the underlying structures. By controlling the reaction conditions and introducing specific gases, the method allows for the growth of high-quality graphene layer 104 on the dielectric layer 102, which can improve the performance of semiconductor devices in BEOL processes.

In some embodiments, the dielectric layer 102 is spaced apart from the filament 206a of the heating belt 206 by a non-zero distance D1 (see FIG. 3B), about 1 cm to 10 cm, such as about 1, 2, 3, 4, 5, 6, 7, 8, 9, or 10 cm. If the distance between the filament 206a and the dielectric layer 102 is less than about 1 cm, it can lead to overheating of the dielectric layer 102, potentially causing damage to the material or degrading its properties. In addition, a short distance may result in uneven heating and an uneven distribution of carbon atoms, leading to non-uniform graphene growth with varying thickness or quality across the dielectric layer 102. Furthermore, when the filament 206a is too close to the dielectric layer 102, the carbon atoms may not have enough time or space to rearrange themselves properly, increasing the likelihood of defects in the graphene lattice in the graphene layer 104. If the distance between the filament 206a and the dielectric layer 102 is greater than about 10 cm, it may lead to inefficient heating of the carbon precursor, resulting in incomplete pyrolysis and a lower yield of carbon atoms available for graphene formation. A longer distance may cause the carbon atoms to cool down and lose their mobility before reaching the dielectric layer 102, making it more difficult for them to rearrange into the graphene lattice and resulting in poor graphene quality. In addition, a greater distance can lead to a slower deposition rate, as the carbon atoms have to travel further to reach the dielectric layer 102, resulting in a longer process time to achieve the desired graphene thickness.

Referring back to FIG. 1, the method M then proceeds to block S104 where the substrate is moved out from the processing chamber of the deposition system. FIGS. 5A-5C illustrate a cross-sectional view, a top view, and a perspective view of the semiconductor structure 100 in accordance with some embodiments. With reference to FIGS. 5A-5C, in some embodiments of block S104, after the heater 208 (see FIG. 4A) is turned off, the substrate 101 is moved out from the processing chamber 200 (see FIG. 4A) of the deposition system 20. In some embodiments, before moving out the substrate 101 from the processing chamber 200, the valve 212 of the gas delivery system 202 may be turned off, so as to stop providing carbon-containing precursor into the processing chamber 200. As shown in FIGS. 5A-5C, the graphene layer 104 can be epitaxially grown on the dielectric layer 102 to form crystalline films. In some embodiments, after the formation of the graphene layer 104 (see FIG. 5C), the graphene layer 104 may be optionally patterned into a patterned transition metal layer by suitable lithography process and etching process. For example, a mask layer (e.g., silicon nitride layer) is deposited over the graphene layer 104, and a photoresist layer is coated over the mask layer and patterned by the lithography process. Subsequently, the mask layer is patterned using the patterned photoresist layer as etch mask. Subsequently, the graphene layer 104 is patterned using the patterned mask layer as etch mask. The patterning may include one or more etching process that etches the material of the graphene layer 104 at a faster rate than etches the mask layer and etches the dielectric layer 102. After the patterning, portions of the graphene layer 104 exposed by the patterned mask layer are etched away by suitable etching process, and portions of the graphene layer 104 covered by the patterned mask layer remain after the etching process.

Referring back to FIGS. 5D and 5E. FIGS. 5D and 5E illustrate experimental results of a Raman spectrum of the graphene layer 104 formed on the dielectric layer 102. Raman spectroscopy is a characterization technique for the graphene layer 104. Carbon-based materials, such as graphene, may have three intense Raman features including a defect band (D band), a band related to in-plan vibration of sp2 carbon (G band), and a stacking order (2D band). For monolayer graphene, the g band has a Raman Shift located at about 1580 cm⁻¹, the d band has a Raman Shift located at about 1350 cm⁻¹, and the 2D band has a raman shift located at about 2700 cm⁻¹. The relative intensity (a.u.) of the g band frequency of Raman spectra may be used as a measure for a number of features that provide information regarding sample purity, geometry, and the metallic or semi-conducting nature of the material. Another prominent feature in the Raman spectra of carbon-based materials is the d band. The d band is sensitive to differences in the carbon network that is characteristic of many carbon-based materials, and the intensity of the d band may provide information on the electronic character of a particular material. Because a carbon lattice may contain aromatic carbons that are sp2 hybridized and may be substantially more conductive, it may be beneficial to select for the graphene layer GL having fewer numbers of non-aromatic sp3 hybridized carbon sites, or “defects” in the carbon lattice. For example, higher intensity in the d band in a Raman spectrum may indicate that a particular sample has a higher concentration of defects and may not be as conductive as a sample having a relatively lower d band intensity.

FIG. 5D illustrate experimental results of a Raman spectrum of the graphene layer 104 formed on the dielectric layer 102 (e.g. silicon oxide) over the substrate 101 (e.g. silicon) at different locations (labeled 1-9 as shown in FIG. 5B) on the dielectric layer 102. The sample including the graphene layer 104 obtained from the HW-CVD process P1 described above were prepared and intensities of Raman shift of the graphene layer were measured, in which the HW-CVD process P1 is performed at a temperature lower than about 400° C. Different locations 1-9 of the graphene layer 104 each has a g band having a Raman Shift located at about 1580 cm⁻¹, the d band having a Raman Shift located at about 1350 cm⁻¹, and the 2d band having a Raman Shift located at about 2700 cm⁻¹, suggesting that different locations 1-9 of the graphene layer 104 are highly graphitized, and the qualities of the graphene layer 104 at different locations (marked as 1-9) are uniformity.

FIG. 5E illustrate experimental results of a Raman spectrum of graphene layers formed on the dielectric layers with introducing ammonia (Cases 1 and 2) or without introducing ammonia (Case 3) on the dielectric materials, in which the dielectric layer in Case 1 is made of silicon nitride, and the dielectric layers in Cases 2 and 3 are made of silicon oxide. Specifically, Case 1 illustrates an experimental result that graphene is formed on a dielectric layer made of silicon nitride (Si₃N₄) with ammonia (NH₃) introduced during the process, Case 2 illustrates an experimental result that graphene is formed on a dielectric layer made of silicon oxide (SiO2) with ammonia (NH3) introduced during the process, and Case 3 illustrates an experimental result that graphene formed on a dielectric layer made of silicon oxide (SiO2) without introducing ammonia (NH₃) during the process. The Raman spectrum is a characterization technique used to analyze the quality, number of layers, and other properties of graphene. By comparing the Raman spectra of the graphene layers formed under these different conditions, the effects of the dielectric material and the introduction of ammonia on the quality and properties of the resulting graphene layers can be observed.

The experimental results discussed above demonstrate that in both Case 1 and Case 2, where ammonia is introduced during the graphene formation process, the Raman spectra exhibit characteristic G, D, and 2D bands with Raman shifts located at approximately 1580 cm-1, 1350 cm-1, and 2700 cm-1, respectively. In contrast, these features are not as prominent in Case 3, where ammonia is not introduced. This indicates that the introduction of ammonia in the process leads to improved crystalline quality and uniformity of the graphene layers formed on the dielectric materials. Furthermore, a comparison between Case 1 and Case 2 reveals that the method disclosed in the present study can be successfully employed to form high-quality graphene layers on different dielectric materials, such as silicon oxide (SiO₂) and silicon nitride (Si₃N₄). Therefore, the inclusion of ammonia during the graphene formation process on dielectric materials can enhance the crystalline quality and uniformity of the resulting graphene layers, demonstrate the effectiveness of the disclosed method across various dielectric materials.

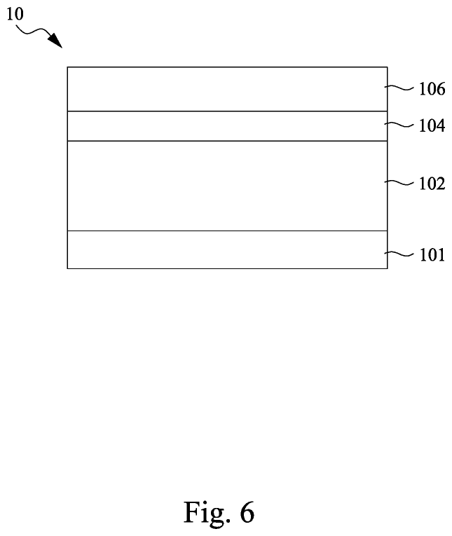

Referring back to FIG. 1, the method M then proceeds to block S105 where a metal layer is deposited on the graphene layer. With reference to FIG. 6, in some embodiments of block S105, the metal layer 106 is deposited over the graphene layer 104. In some embodiments, the metal layer 106 may be made of a conductive material, such as iron (Fe), cobalt (Co), nickel (Ni), copper (Cu), platinum (Pt), palladium (Pd), aluminum (Al), tungsten (W), ruthenium (Ru), Au, Ti, Ta, TiN, TaN, proper alloys thereof, the like, suitable materials, or combinations thereof. In some embodiments, the metal layer 106 may be formed by a deposition process, such as a physical vapor deposition (PVD) process (e.g., e-gun evaporation deposition or thermal evaporation deposition), an atomic layer deposition (ALD), a chemical vapor deposition (CVD), the like, or combinations thereof.

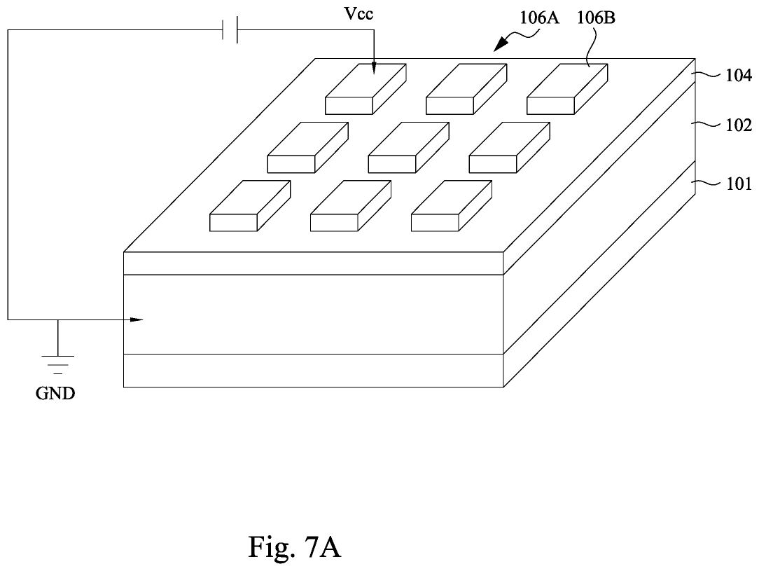

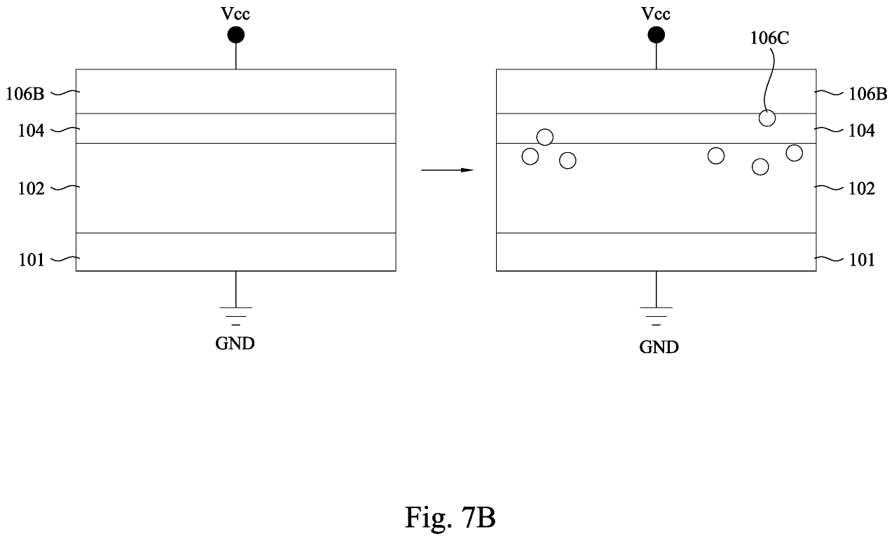

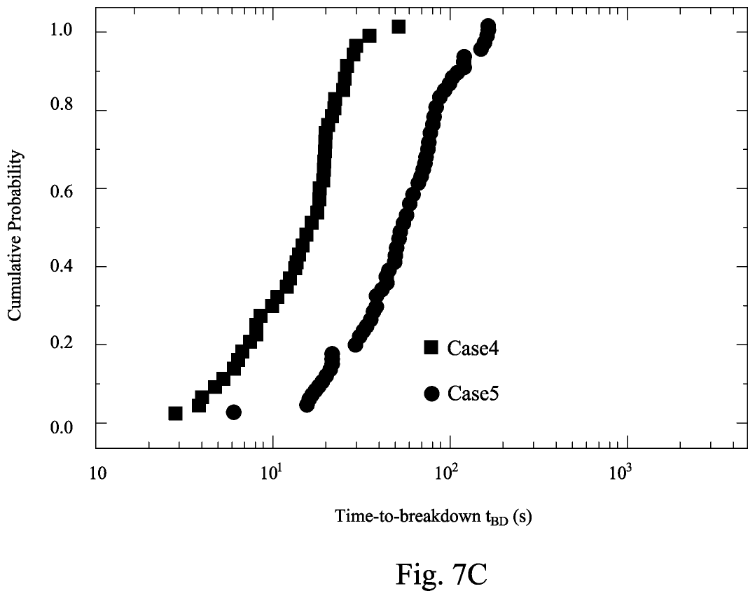

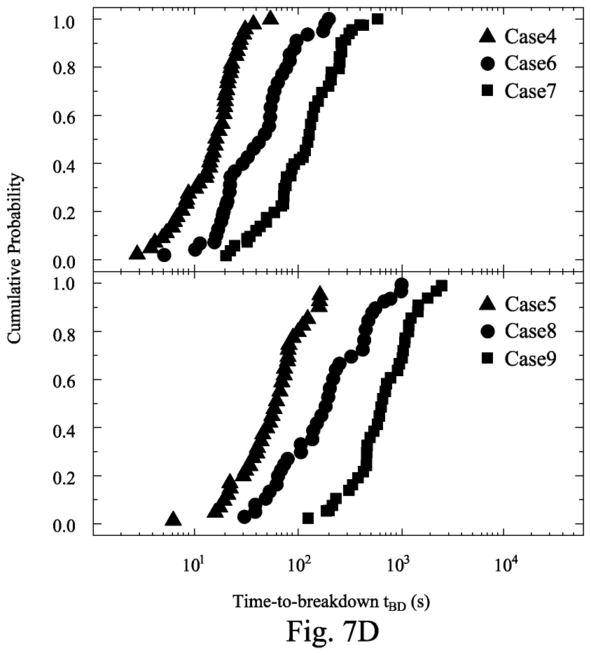

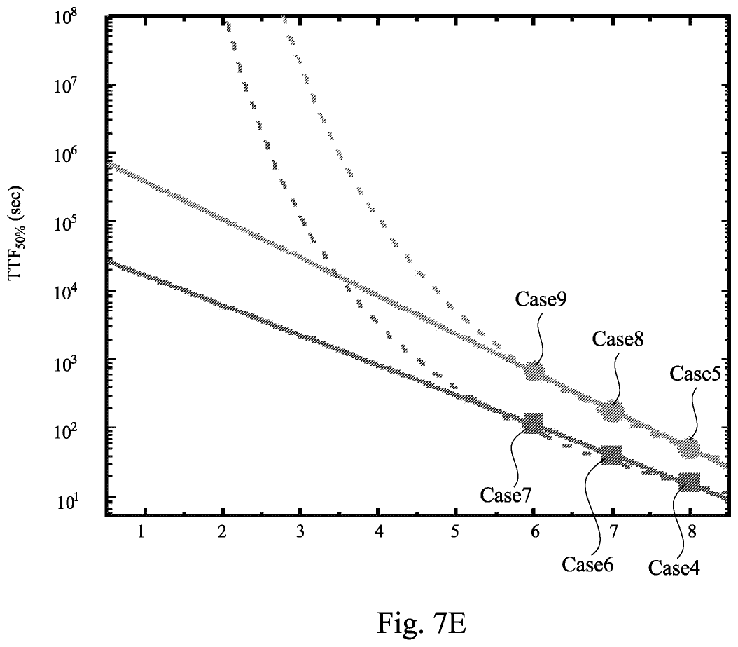

Referring back to FIG. 1, the method M then proceeds to block S106 where the metal layer is patterned into a plurality of metal electrodes. With reference to FIG. 7A, in some embodiments of block S106, after the deposition of the metal layer 106, the metal layer 106 may be optionally patterned into a patterned metal layer by suitable lithography process and etching process. For example, a mask layer (e.g., silicon nitride layer) is deposited over the metal layer 106, and a photoresist layer is coated over the mask layer and patterned by the lithography process. Subsequently, the mask layer is patterned using the patterned photoresist layer as etch mask. Then, the metal layer 106 is patterned using the patterned mask layer as etch mask. The patterning may include one or more etching process that etches the material of the metal layer 106 at a faster rate than etches the mask layer and etches the graphene layer 104 and the dielectric layer 102. After the patterning, portions of the metal layer exposed by the patterned mask layer are etched away by suitable etching process, and portions of the metal layer covered by the patterned mask layer remain after the etching process. In some embodiments, the metal layer 106 may be patterned into a metal electrode array 106A. The metal electrode array 106A includes several metal electrodes 106B arranged in a predetermined pattern and is disposed on a surface of the underlying graphene layer 104. In some embodiments, the patterning generates the metal electrode array 106A having a separation SI between two adjacent metal electrodes 106B.

Reference is made to FIGS. 7B-7E. FIG. 7B illustrate a method of performing time dependent dielectric breakdown (TDDB) measurement on the semiconductor structure 100 with the graphene layer 104 as the diffusion barrier layer in accordance with some embodiments of the present disclosure. FIGS. 7C-7E are TDDB measurement results of semiconductor structure with and without a graphene as the barrier in accordance with some embodiments of the present disclosure. The TDDB measurement is a reliability testing method used to evaluate the degradation and failure of the graphene layer 104 in semiconductor device under long-term electrical stress. Dielectric breakdown occurs when the insulating properties of the graphene layer 104 are compromised due to the applied electric field, leading to an abrupt increase in current flow and ultimately device failure. The TDDB measurement involves applying a constant voltage or current across the graphene layer 104 while monitoring the leakage current over an extended period due to metal species 106c of the metal electrodes 106B (see FIG. 7B) diffuses to the dielectric layer 102 through the graphene layer 104. The time it takes for the graphene layer 104 to break down under the applied stress is recorded, and this data is used to predict the lifetime and reliability of the graphene layer 104 under various operating conditions. The results of TDDB measurements can also provide insights into the failure mechanisms and potential areas for improvement in the graphene layer 104 or device design.

As shown in FIG. 7B, the graphene layer 104 is sandwiched between the dielectric layer 102 and the metal electrode 106B. The metal electrode 106B is provided with a higher voltage Vcc with respect to the ground GND, and the substrate 101 below the dielectric layer 102 is electrically coupled to the ground GND. In some embodiments, the graphene layer 104 has a thinner thickness than the substrate 101, the dielectric layer 102, and the metal electrode 106B. By way of example but not limiting the present disclosure, the graphene layer 104 has a thickness less than about 2 nm. In some embodiments, the dielectric layer 102 may have a thickness in a range from about 50 nm to about 150 nm, such as about 50, 60, 70, 80, 90, 100, 110, 120, 130, 140, or 150 nm. In some embodiments, the metal electrode 106B may have a thickness in a range from about 50 nm to about 150 nm, such as about 50, 60, 70, 80, 90, 100, 110, 120, 130, 140, or 150 nm.

In FIG. 7C, the graphene in the experimental samples are prepared at a temperature below 400 degrees Celsius with a deposition time of approximately 30 seconds, and is directly formed on the dielectric material (e.g., SiO₂). Following the structure illustrated in FIG. 7B, Case 4 represents a device without graphene, while Case 5 includes a graphene barrier layer. The lifetime of Case 4 is found to be around 14 seconds, whereas the lifetime of Case 5 is significantly longer, at approximately 50 seconds. These results demonstrate that employing graphene as a diffusion barrier can substantially extend the device lifetime, in this instance, by at least three times. This finding highlights the benefits of using the disclosed method for incorporating graphene as a barrier layer in semiconductor structures.

In FIGS. 7D and 7E, in the experimental samples, graphene is prepared at a temperature below 400 degrees Celsius with a deposition time of approximately 30 seconds and is directly formed on the dielectric material (e.g. SiO₂). In FIG. 7D, following the structure depicted in FIG. 7B, Cases 4, 6, and 7 represent devices without graphene and are subjected to applied voltages of 8, 7, and 6 MV/cm, respectively. In contrast, Cases 5, 8, and 9 feature devices with graphene barrier layers and are exposed to the same respective applied voltages of 8, 7, and 6 MV/cm. The observed lifetimes for Cases 4, 6, and 7 are approximately 14 seconds, 38 seconds, and 111 seconds, respectively. Meanwhile, the lifetimes for Cases 5, 8, and 9 are significantly longer, at about 50 seconds, 173 seconds, and 642 seconds, respectively. These results demonstrate that incorporating graphene as a diffusion barrier can substantially extend the device lifetime under various applied voltages. This evidence underscores the advantages of employing the disclosed method for integrating graphene as a barrier layer in semiconductor structures across a range of voltage conditions. In FIG. 7E, Cases 4, 6, 7, 5, 8, and 9 are plotted on a graph, with the electric field (MV/cm) represented on the horizontal axis and Time to Failure (TTF) at 50% probability (in seconds) on the vertical axis. Separate trendlines are drew for cases with graphene (e.g., Cases 5, 8, and 9) and those without graphene (e.g., Cases 4, 6, and 7) to predict the lifetime of the experiment samples. The graph illustrates that, under varying electric fields (MV/cm), the devices exhibit longer lifetimes when graphene is employed as the barrier layer for the metal wire. By incorporating graphene as a barrier layer in semiconductor structures, the lifetime of the devices can be significantly extended across a range of electric field conditions, thereby enhancing their reliability and performance.

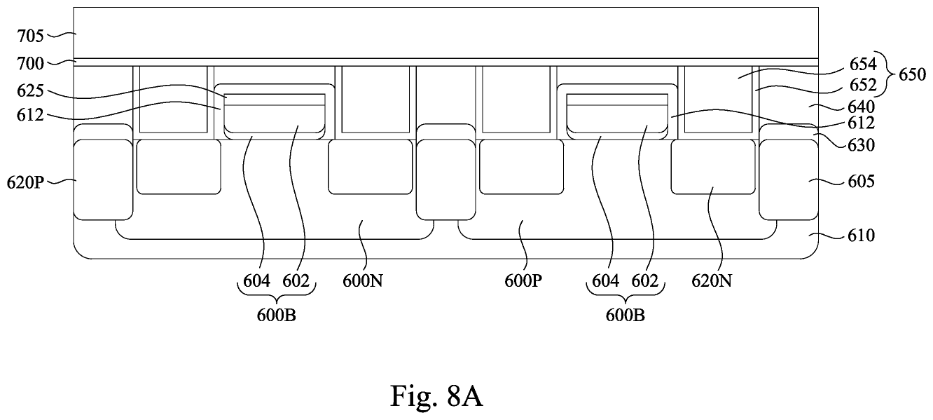

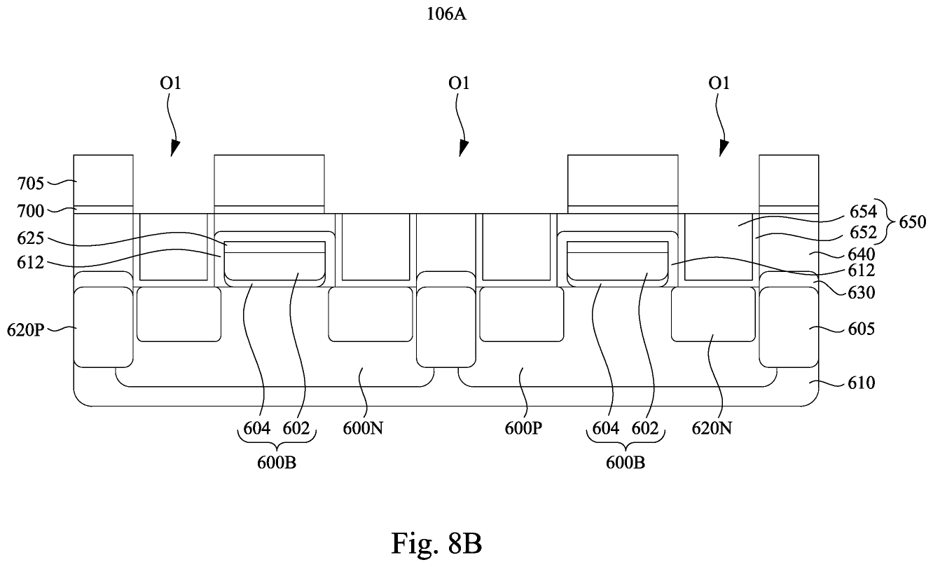

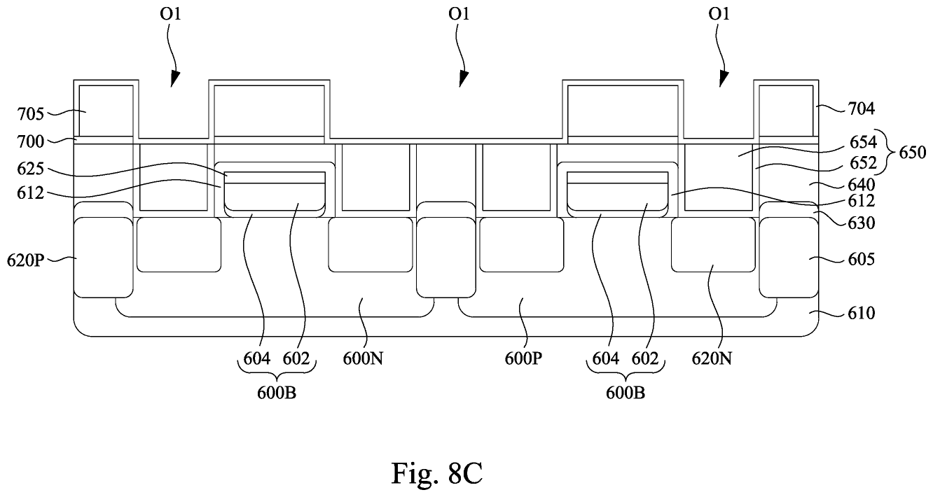

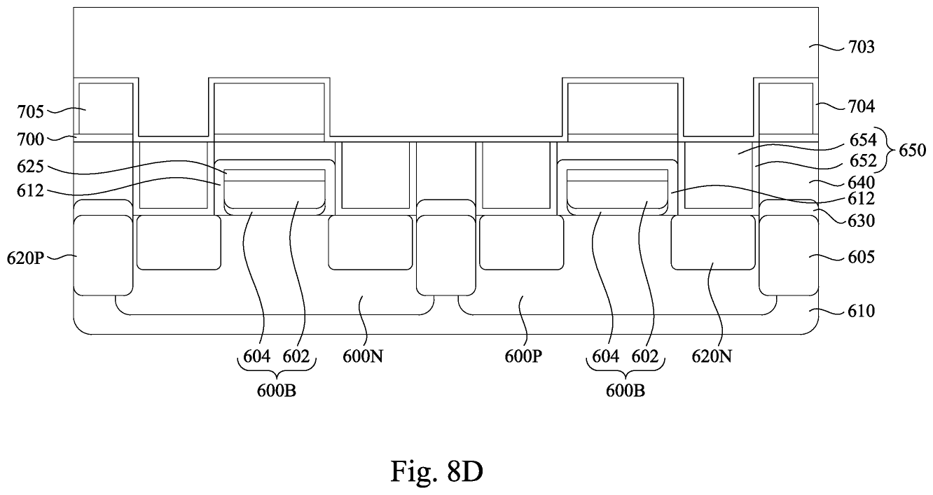

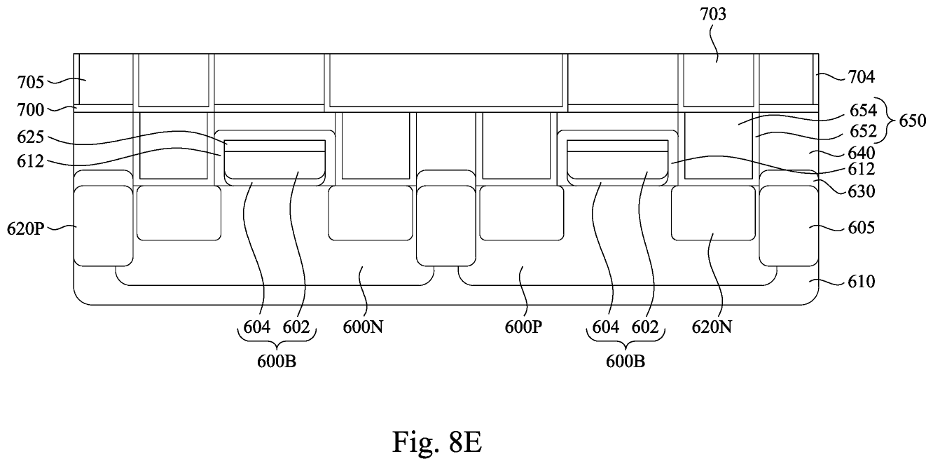

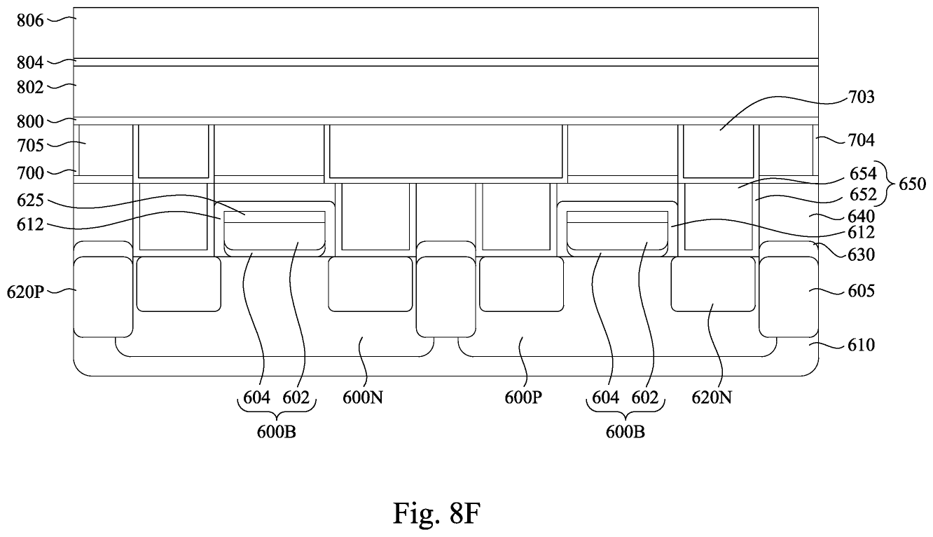

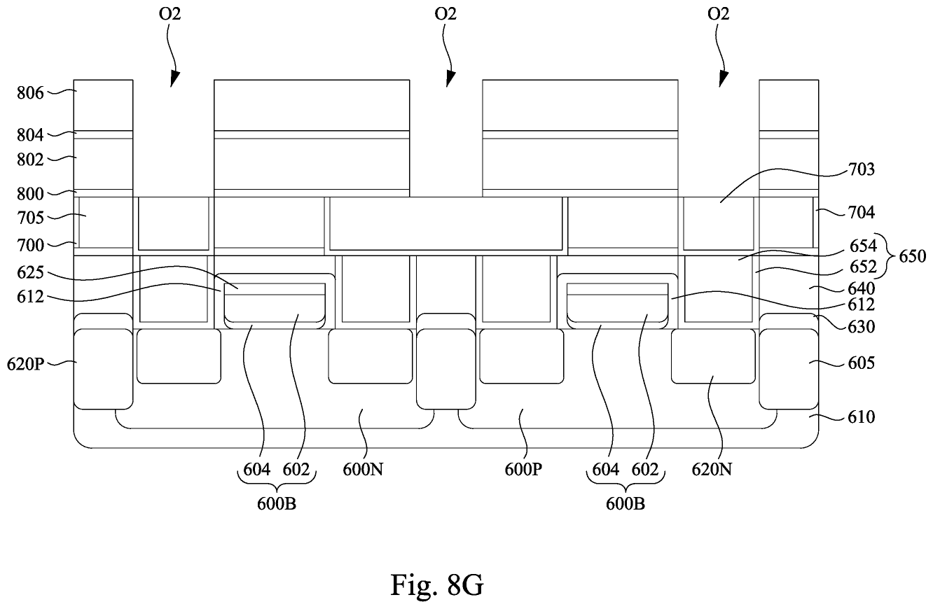

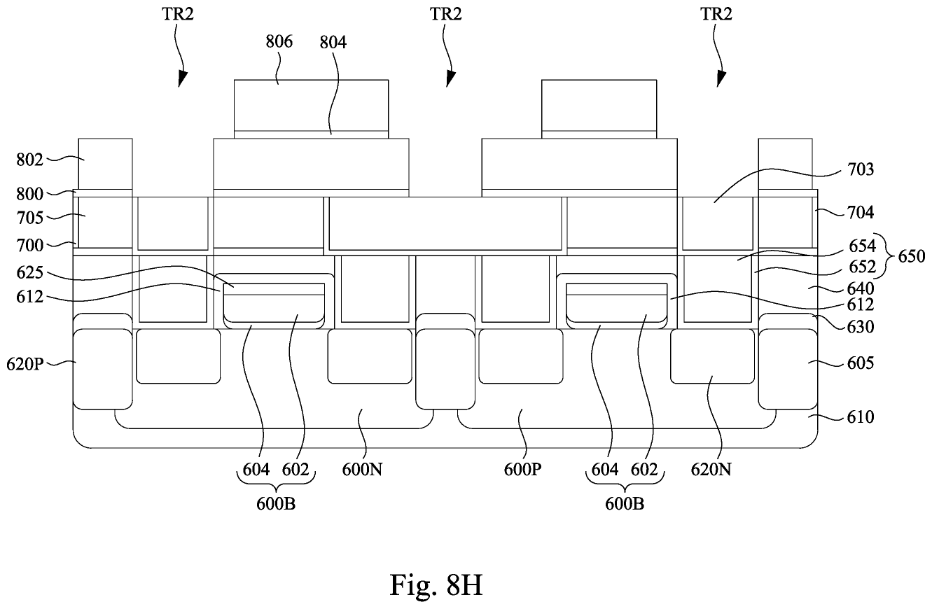

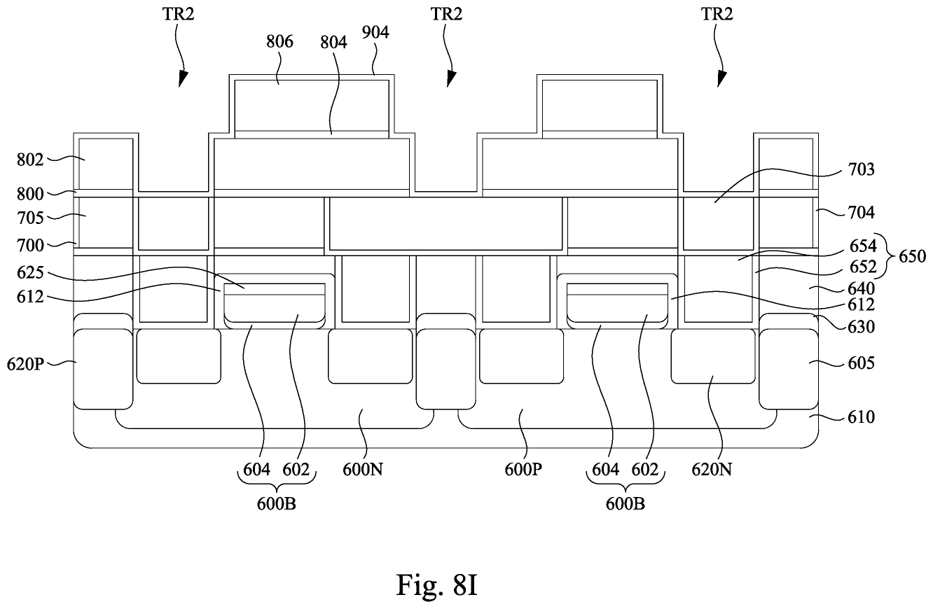

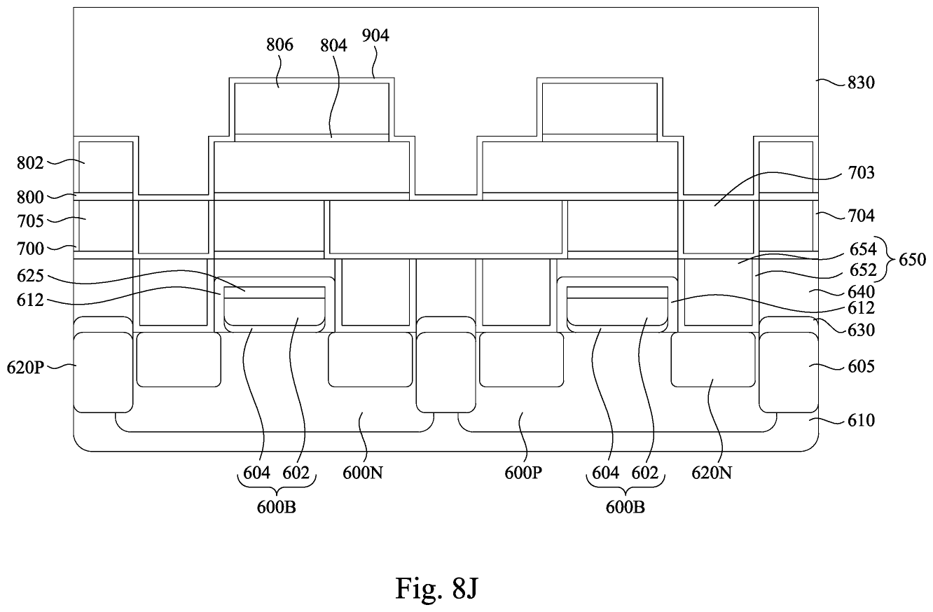

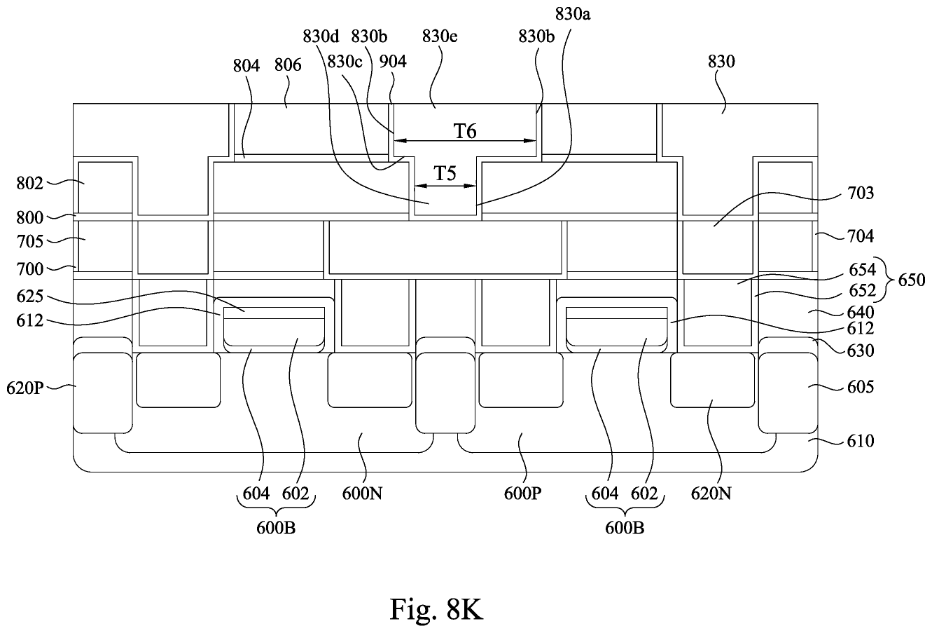

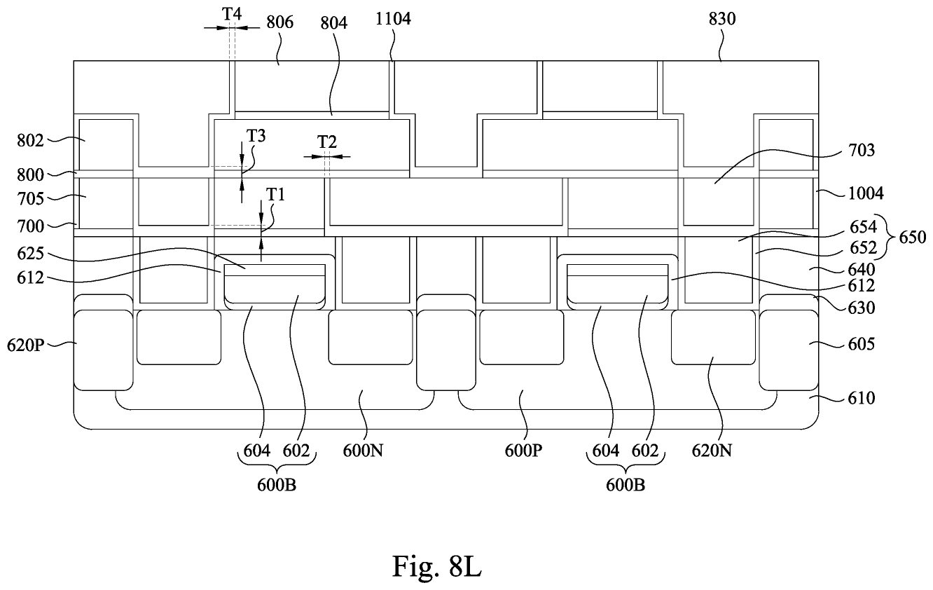

Reference is made to FIGS. 8A-8K. FIGS. 8A-8K illustrate a method in various stages of forming a semiconductor device in accordance with some embodiments of the present disclosure. Reference is made to FIG. 8A. An initial structure is received. The initial structure includes a substrate 610. The substrate 610 includes an N-well region 600N and a P-well region 600P, in which the N-well region 600N may be doped with N-type impurities, and the P-well region 600P may be doped with P-type impurities. The substrate 610 may be a semiconductor material and may include known structures including a graded layer or a buried oxide, for example. Other materials, such as germanium, quartz, sapphire, and glass could alternatively be used for the substrate 610. Alternatively, the silicon substrate 610 may be an active layer of a semiconductor-on-insulator (SOI) substrate or a multi-layered structure such as a silicon-germanium layer formed on a bulk silicon layer.

Isolation structures 605 are disposed in the substrate 610. In some embodiments, the isolation structures 605 may include oxide, such as silicon dioxide. The isolation structures 605, which act as a shallow trench isolation (STI) around the P-well region 600P from the N-well region 600N, may be formed by chemical vapor deposition (CVD) techniques using tetra-ethyl-ortho-silicate (TEOS) and oxygen as a precursor.

A gate structure 600A is disposed over the P-well region 600P of the substrate 610, and a gate structure 600B is disposed over the N-well region 600N of the substrate 610. In some embodiments, each of the gate structure 600A and the gate structure 600B includes a gate dielectric 602 and a gate electrode 604. In some embodiments, the gate dielectric 602 may be, for example, silicon oxide, silicon nitride, a combination thereof, or the like, and may be deposited or thermally grown according to acceptable techniques. In some embodiments, the gate electrode 604 may include polycrystalline-silicon (poly-Si) or poly-crystalline silicon-germanium (poly-SiGe). In some other embodiments, the gate structure 600A and the gate structure 600B may be metal gate structures, which include a high-k dielectric layer, a work function metal layer over the high-k dielectric layer, and a gate metal over the work function metal layer.

Capping layers 625 are disposed over the gate structures 600A and 600B. In some embodiments, the capping layers 625 may be oxide. A plurality of gate spacers 612 are disposed on opposite sides of the gate structure 600A and the gate structure 600B. In some embodiments, the gate spacers 612 may include SiO₂, Si₃N₄, SiOₓN_{y}, SiC, SiCN films, SiOC, SiOCN films, and/or combinations thereof.

Source/drain structures 620N are disposed in the P-well region 620P of the substrate 610 and on opposite sides of the gate structure 600A, and source/drain structures 620P are disposed in the N-well region 620N of the substrate 610 and on opposite sides of the gate structure 600B. In some embodiments, the source/drain structures 620N may be doped with N-type impurities, and the source/drain structures 620P may be doped with p-type impurities. In some embodiments, the source/drain structures 620N, 620P may be may be formed by performing an epitaxial growth process that provides an epitaxy material over the substrate 610, and thus the source/drain structures 620N, 620P can be interchangeably referred to as epitaxy structures 620N, 620P in this context. In various embodiments, the source/drain structures 620N, 620P may include Ge, Si, GaAs, AlGaAs, SiGe, GaAsP, SiP, or other suitable materials.

A contact etch stop layer (CESL) 630 is disposed over the isolation structures 605 and over the capping layers 625. An interlayer dielectric (ILD) layer 640 is disposed over the CESL 630 and surrounds the gate structures 600A and 600B. In some embodiments, the CESL 630 includes silicon nitride, silicon oxynitride or other suitable materials. The CESL 630 can be formed using, for example, plasma enhanced CVD, low pressure CVD, ALD or other suitable techniques. In some embodiments, the ILD layer 640 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide. The ILD layer 640 may be formed using, for example, CVD. ALD, spin-on-glass (SOG) or other suitable techniques.

Source/drain contacts 650 are disposed in the ILD layer 640 and contact the source/drain structures 620A and 620P. In some embodiments, each source/drain contact 650 includes a liner 652 and a plug 654. The liner 652 is between the plug 654 and the underlying source/drain structures 600A or 600B. In some embodiments, the liner 652 assists with the deposition of the plug 654 and helps to reduce diffusion of a material of the plug 654 through the gate spacers 612. In some embodiments, the liner 652 includes titanium (Ti), titanium nitride (TiN), tantalum (Ta), tantalum nitride (TaN), or another suitable material. The plug 654 includes a conductive material, such tungsten (W), copper (Cu), aluminum (Al), ruthenium (Ru), cobalt (Co), molybdenum (Mo), nickel (Ni), or other suitable conductive materials. In some embodiments, the plug 654 can be interchangeably referred to as a source/drain contact.

An etch stop layer (ESL) 700 is disposed over the ILD layer 640 and the source/drain contacts 650. An inter-metal dielectric (IMD) layer 705 is disposed over the ESL 700. The material and the formation method of the ESL 700 are similar to those of the CESL 630. Moreover, the material and the formation method of the IMD layer 705 are similar to those of the ILD layer 640.

Reference is made to FIGS. 8B and 8C. The ESL 700 and the IMD layer 705 are patterned to form openings O1 (see FIG. 8B) to expose the source/drain contacts 650, and then a graphene layer 704 (see FIG. 8C) is conformally formed over the IMD layer 705, the ESL 700, and in the openings O1. In some embodiments, the substrate 610 is moved into a processing chamber 200 (see FIG. 4A) of a deposition system 20 and on a carrier 209. The HW-CVD process P1 is performed to form the graphene layer 704 on the IMD layer 705 and the ESL 700 and also on the source/drain contacts 650. During the HW-CVD process P1, the IMD layer 705, the ESL 700, and the source/drain contact 650 are exposed to an environment rich (e.g., processing chamber 200 as shown in FIG. 4A) in carbon. The high carbon concentration allows carbon atoms to adsorb onto the surfaces of the IMD layer 705, the ESL 700, and the source/drain contact 650.

Specifically, the IMD layer 705, the ESL 700, and the source/drain contact 650 are heated to a predetermined temperature, such as about 300 to 400° C., through the heater 208 in an atmosphere with a carrier gas mixture including hydrogen (H₂), argon (Ar), and ammonia (NH₃). The carrier gas mixture is introduced into the processing chamber 200 from the sources 212, 214, and 218 through the gas delivery line G1. In some embodiments, the argon carrier gas may be performed with a flow rate in a range from between about 20 sccm to about 200 sccm, such as about 20, 25, 50, 75, 100, 125, 150, 175, or 200 sccm. In some embodiments, the hydrogen carrier gas may be performed with a flow rate in a range from between about 20 sccm to about 200 sccm, such as about 20, 25, 50, 75, 100, 125, 150, 175, or 200 sccm. In some embodiments, the flow rate of the ammonia precursor is less than about 0.1% of the flow rate of the carbon precursor. In some embodiments, the flow rate of the ammonia precursor is in a range from about 0.01% to 0.1% of the sum of the flow rates of all other carrier gases (e.g., the sum of the flow rates of argon carrier gas, hydrogen carrier gas, and carbon precursor). By way of example but not limiting the present disclosure, the ammonia precursor may be performed with a flow rate in a range from between about 0.04 sccm to about 0.4 sccm, such as about 0.04, 0.08, 0.1, 0.15, 0.2, 0.25, 0.3, 0.35, or 0.4 sccm.

Subsequently, a carbon precursor in a gas state is introduced into the processing chamber 200 under a process pressure in a range from about 1 to about 20 Torr, such as about 1, 2, 3, 4, 5, 6, 7, 8, 9, 10, 11, 12, 13, 14, 15, 16, 17, 18, 19, or 20 Torr, from the source 212. The carbon precursor may include a carbon-containing material, such as methane, ethane, propane, ethene, propene, acetylene, other suitable material, or combinations thereof. In some embodiments, the carbon precursor may be performed with a flow rate in a range from between about 3 sccm to about 150 sccm, such as about 3, 10, 20, 30, 40, 50, 60, 70, 80, 90, 100, 110, 120, 130, 140, or 150 sccm. The carbon precursor is pyrolyzed by the filament 206a of the heating belt 206. The carbon precursor is cracked to broken the carbon precursor down into carbon atoms, by the breaking of carbon-carbon bonds and/or carbon-hydrogen bonds in the carbon precursor. In some embodiments, the filament 206a is performed to heat to a temperature that the carbon precursor can be pyrolyzed, the temperature can be in a range from about 2000 to 3000° C., such as about 2000, 2100, 2200, 2277, 2300, 2400, 2500, 2527, 2600, 2700, 2800, 2900, or 3000° C.

In some embodiments, the carbon rich environment is maintained for about 5 to about 30 minutes to allow the graphene layer 704 to grow on the IMD layer 705, the ESL 700, and the source/drain contact 650. In addition, the temperature of the environment around the substrate 610 in the processing chamber 200 is controlled to maintain between about 300 and 400 degrees Celsius to prevent carbon atoms from rebonding or forming an amorphous state on the surfaces of the IMD layer 705, the ESL 700, and the source/drain contact 650. When the temperature is between 300 and 400 degrees Celsius, the surface energies of the IMD layer 705, the ESL 700, and the source/drain contact 650 increases due to the increased thermal energy. The increase in surface energy has the following effects, which can help carbon atoms to form graphene on the surface of the dielectric material. For example, with increased surface energy, the IMD layer 705, the ESL 700, and the source/drain contact 650 become more reactive, which can promote the adsorption of carbon atoms on the surface. This ensures a sufficient density of carbon atoms necessary for the formation of a high-quality graphene layer. In addition, carbon atoms gain enough energy to move across the surfaces of the IMD layer 705, the ESL 700, and the source/drain contact 650. This mobility allows carbon atoms to find energetically favorable positions and form the stable, two-dimensional honeycomb lattice structure characteristic of graphene. Furthermore, the increased surface energy also lowers the energy barrier for carbon atoms to rearrange themselves into the graphene lattice. This makes the formation of the graphene layer more thermodynamically favorable and ensures a well-ordered, high-quality graphene layer. This temperature decrease induces the adsorbed carbon atoms to arrange themselves into a two-dimensional honeycomb lattice structure, crystallizing into graphene on the surfaces of the IMD layer 705, the ESL 700, and the source/drain contact 650. By following this process and controlling the reaction conditions, such as temperature, gas flow rates, and catalyst presence, it is possible to grow high-quality graphene layers on the surfaces of the IMD layer 705, the ESL 700, and the source/drain contact 650, which can then be used in various applications. In some embodiments, the process temperature range can depend on the selected carbon source or inorganic source of material. For example, when methane is used, the temperature for graphene growth can be higher than when benzene is used. In some embodiments, pyrolyzing the carbon precursor includes providing a current in a range from about 4 to about 6 A, such as about 4, 4.5, 4.58, 5, 5.04, 5.5, or 6 A, on the filament 206a (see FIG. 4A).

In some embodiments, ammonia (NH₃) is introduced near the surfaces of the IMD layer 705, the ESL 700, and the source/drain contact 650 to react with the unpyrolyzed hydrocarbon precursors. The reaction between ammonia and the hydrocarbon gas forms intermediate compounds, such as imines or amines, and releases carbon atoms near the surface of the dielectric material:

C₂H₂+2NH₃→C₂+2NH₄

This reaction ensures that the environment near the surfaces of the IMD layer 705, the ESL 700, and the source/drain contact 650 remains saturated with carbon, promoting the adsorption of carbon atoms onto the surface. Further, when the temperature around the substrate 610 in the processing chamber 200 is between 300 and 400 degrees Celsius, the reaction kinetics between the ammonia (NH₃) and carbon precursor, ensuring that carbon atoms are continuously supplied to the dielectric surface. This further facilitates the formation of graphene by maintaining a carbon-saturated environment near the surface.

After achieving the desired carbon atom coverage on the dielectric surface, the temperature of the environment around the substrate 610 in the processing chamber 200 is lowered to below 300 degrees Celsius. In some embodiments, when using the above-disclosed method to form the graphene layer 704 over the substrate 610, the thickness of the graphene layer 704 formed on a metal (e.g., filling metal 703) may be greater than that on a dielectric material (e.g., the IMD layer 705, the ESL 700), and the detailed description can refer to FIG. 8L.

Reference is made to FIG. 8D. A filling metal 703 is deposited over the graphene layer 704 and fills the openings O1 (see FIG. 8C). In some embodiments, the filling metal 703 is made of a conductive material. In some embodiments, the conductive material may include iron (Fe), cobalt (Co), nickel (Ni), copper (Cu), platinum (Pt), palladium (Pd), aluminum (Al), tungsten (W), ruthenium (Ru), Ti, Ta, TiN, TaN, proper alloys thereof, suitable materials, or combinations thereof. In some embodiments, the conductive material may be deposited by CVD, physical vapor deposition (PVD), sputter deposition, ALD, electroplating, or other techniques suitable for depositing conductive materials.

Reference is made to FIG. 8E. A chemical mechanical polishing (CMP) process is performed to remove excessive materials of the filling metal 703 and the graphene layer 704 until the IMD layer 705 is exposed. In some embodiments, the remaining filling metal 703 can be referred to as a metal-1 (M1) layer in a back end of line (BEOL) process. In some embodiments, the filling metal 703 in FIG. 8E can be interchangeably referred to as a metal line, a metal wire, a conductive line, a conductive wire, a conductive layer, a conductive pattern, an interconnect, or a conductor. In some embodiments, the portion of the graphene layer 704 (e.g., the graphene layer 904 on a bottom surface of the filling metal 703) that contacts with the source/drain contact 650 is thicker than the portion that does not contact with the source/drain contact 650 (see FIG. 8L).

Reference is made to FIG. 8F. An ESL 800, an IMD layer 802, an ESL 804, and an IMD layer 806 are formed sequentially over the IMD layer 705. The ESLs 800 and 804 are similar to the ESL 700, the IMD layers 802 and 806 are similar to the IMD layer 705, and thus relevant details will not be repeated for brevity.

Reference is made to FIG. 8G. The ESL 800, the IMD layer 802, the ESL 804, and the IMD layer 806 are patterned to form via openings O2. In some embodiments, via openings O2 may be formed by, for example, forming a patterned photoresist layer over the IMD layer 806, followed by an etching process to remove portions of the ESL 800, the IMD layer 802, the ESL 804, and the IMD layer 806, and then removing the photoresist layer.

Reference is made to FIG. 8H. The ESL 804 and the IMD layer 806 are patterned to form trenches TR2 that are aligned above the via openings O2. In some embodiments, the trenches TR2 may be formed by, for example, forming a patterned photoresist layer over the IMD layer 806, followed by an etching process to remove portions of the ESL 804, and the IMD layer 806, and then removing the photoresist layer.

Reference is made to FIG. 8I. A graphene layer 904 is conformally formed over the IMD layers 802 and 806, the ESLs 800 and 804, and in the trenches TR2 and the openings O2. In some embodiments, the substrate 610 is moved into a processing chamber 200 (see FIG. 4A) of a deposition system 20 and on a carrier 209. The HW-CVD process P1 is performed to form the graphene layer 904 on the IMD layers 802 and 806, the ESLs 800 and 804 and also on the source/drain contacts 650. During the HW-CVD process P1, the IMD layers 802 and 806, the ESLs 800 and 804, and the filling metal 703 are exposed to an environment rich (e.g., processing chamber 200 as shown in FIG. 4A) in carbon. The high carbon concentration allows carbon atoms to adsorb onto the surfaces of the IMD layers 802 and 806, the ESLs 800 and 804, and the filling metal 703.

Specifically, the IMD layers 802 and 806, the ESLs 800 and 804, and the filling metal 703 are heated to a predetermined temperature, such as about 300 to 400° C., through the heater 208 in an atmosphere with a carrier gas mixture including hydrogen (H₂), argon (Ar), and ammonia (NH₃). The carrier gas mixture is introduced into the processing chamber 200 from the sources 212, 214, and 218 through the gas delivery line G1. In some embodiments, the argon carrier gas may be performed with a flow rate in a range from between about 20 sccm to about 200 sccm, such as about 20, 25, 50, 75, 100, 125, 150, 175, or 200 sccm. In some embodiments, the hydrogen carrier gas may be performed with a flow rate in a range from between about 20 sccm to about 200 sccm, such as about 20, 25, 50, 75, 100, 125, 150, 175, or 200 sccm. In some embodiments, the flow rate of the ammonia precursor is less than about 0.1% of the flow rate of the carbon precursor. In some embodiments, the flow rate of the ammonia precursor is in a range from about 0.01% to 0.1% of the sum of the flow rates of all other carrier gases (e.g., the sum of the flow rates of argon carrier gas, hydrogen carrier gas, and carbon precursor). By way of example but not limiting the present disclosure, the ammonia precursor may be performed with a flow rate in a range from between about 0.04 sccm to about 0.4 sccm, such as about 0.04, 0.08, 0.1, 0.15, 0.2, 0.25, 0.3, 0.35, or 0.4 sccm.

Subsequently, a carbon precursor in a gas state is introduced into the processing chamber 200 under a process pressure in a range from about 1 to about 20 Torr, such as about 1, 2, 3, 4, 5, 6, 7, 8, 9, 10, 11, 12, 13, 14, 15, 16, 17, 18, 19, or 20 Torr, from the source 212. The carbon precursor may include a carbon-containing material, such as methane, ethane, propane, ethene, propene, acetylene, other suitable material, or combinations thereof. In some embodiments, the carbon precursor may be performed with a flow rate in a range from between about 3 sccm to about 150 sccm, such as about 3, 10, 20, 30, 40, 50, 60, 70, 80, 90, 100, 110, 120, 130, 140, or 150 sccm. The carbon precursor is pyrolyzed by the filament 206a of the heating belt 206. The carbon precursor is cracked to broken the carbon precursor down into carbon atoms, by the breaking of carbon-carbon bonds and/or carbon-hydrogen bonds in the carbon precursor. In some embodiments, the filament 206a is performed to heat to a temperature that the carbon precursor can be pyrolyzed, the temperature can be in a range from about 2000 to 3000° C., such as about 2000, 2100, 2200, 2277, 2300, 2400, 2500, 2527, 2600, 2700, 2800, 2900, or 3000° C.

In some embodiments, the carbon rich environment is maintained for about 5 to about 30 minutes to allow the graphene layer 904 to grow on the IMD layers 802 and 806, the ESLs 800 and 804, and the filling metal 703. In addition, the temperature of the environment around the substrate 610 in the processing chamber 200 is controlled to maintain between about 300 and 400 degrees Celsius to prevent carbon atoms from rebonding or forming an amorphous state on the surfaces of the IMD layers 802 and 806, the ESLs 800 and 804, and the filling metal 703. When the temperature is between 300 and 400 degrees Celsius, the surface energies of the IMD layers 802 and 806, the ESLs 800 and 804, and the filling metal 703 increases due to the increased thermal energy. The increase in surface energy has the following effects, which can help carbon atoms to form graphene on the surface of the dielectric material. For example, with increased surface energy, the IMD layers 802 and 806, the ESLs 800 and 804, and the filling metal 703 become more reactive, which can promote the adsorption of carbon atoms on the surface. This ensures a sufficient density of carbon atoms necessary for the formation of a high-quality graphene layer. In addition, carbon atoms gain enough energy to move across the surfaces of the IMD layers 802 and 806, the ESLs 800 and 804, and the filling metal 703. This mobility allows carbon atoms to find energetically favorable positions and form the stable, two-dimensional honeycomb lattice structure characteristic of graphene. Furthermore, the increased surface energy also lowers the energy barrier for carbon atoms to rearrange themselves into the graphene lattice. This makes the formation of the graphene layer more thermodynamically favorable and ensures a well-ordered, high-quality graphene layer. This temperature decrease induces the adsorbed carbon atoms to arrange themselves into a two-dimensional honeycomb lattice structure, crystallizing into graphene on the surfaces of the IMD layers 802 and 806, the ESLs 800 and 804, and the filling metal 703. By following this process and controlling the reaction conditions, such as temperature, gas flow rates, and catalyst presence, it is possible to grow high-quality graphene layers on the surfaces of the IMD layers 802 and 806, the ESLs 800 and 804, and the filling metal 703, which can then be used in various applications. In some embodiments, the process temperature range can depend on the selected carbon source or inorganic source of material. For example, when methane is used, the temperature for graphene growth can be higher than when benzene is used. In some embodiments, pyrolyzing the carbon precursor includes providing a current in a range from about 4 to about 6 A, such as about 4, 4.5, 4.58, 5, 5.04, 5.5, or 6 A, on the filament 206a (see FIG. 4A).

In some embodiments, ammonia (NH₃) is introduced near the surfaces of the IMD layers 802 and 806, the ESLs 800 and 804, and the filling metal 703 to react with the unpyrolyzed hydrocarbon precursors. The reaction between ammonia and the hydrocarbon gas forms intermediate compounds, such as imines or amines, and releases carbon atoms near the surface of the dielectric material:

C₂H₂+2NH₃→C₂+2NH₄

This reaction ensures that the environment near the surfaces of the IMD layers 802 and 806, the ESLs 800 and 804, and the filling metal 703 remains saturated with carbon, promoting the adsorption of carbon atoms onto the surface. Further, when the temperature around the substrate 610 in the processing chamber 200 is between 300 and 400 degrees Celsius, the reaction kinetics between the ammonia (NH₃) and carbon precursor, ensuring that carbon atoms are continuously supplied to the dielectric surface. This further facilitates the formation of graphene by maintaining a carbon-saturated environment near the surface. After achieving the desired carbon atom coverage on the dielectric surface, the temperature of the environment around the substrate 610 in the processing chamber 200 is lowered to below 300 degrees Celsius.

Reference is made to FIG. 8J. A filling metal 830 is deposited over the graphene layer 904 and fills the via openings O2 and the trenches TR2. The filling metal 830 is similar to the filling metal 703, and thus relevant details will not be repeated hereinafter.

Reference is made to FIG. 8K. A chemical mechanical polishing (CMP) process is performed to remove excessive materials of the filling metal 830 and the graphene layer 904 until the IMD layer 806 is exposed. In some embodiments, the remaining filling metal 830 can be referred to as a metal-2 (M2) layer in a back end of line (BEOL) process. In some embodiments, the filling metal 830 in FIG. 8K can be interchangeably referred to as a metal line, a metal wire, a conductive line, a conductive wire, a conductive layer, a conductive pattern, an interconnect, or a conductor. In some embodiments, the filling metal 830 in FIG. 8K can be interchangeably referred to as a dual damascene construction. The via opening O2 and the trench TR2 can be collectively referred to as dual damascene opening. The filling metal 830 can be a stepped sidewall structure (e.g., two step shape) having a lower sidewall 830a, an upper sidewall 830b laterally set back from the lower sidewall 830a, and a horizontal surface 830c connecting the lower sidewall 830a to the upper sidewall 830b. On the other hand, as shown in FIG. 8K, the filling metal 830 has a lower cross-sectional profile 830d and an upper cross-sectional profile 830e over the lower cross-sectional profile 830d. The lower cross-sectional profile 830d has two opposite lower sidewall 830a, the upper cross-sectional profile 830e has two opposite upper sidewall 830b, and a distance T6 between the two opposite upper sidewall 830b is greater than a distance T5 between the two opposite lower sidewall 830a. As shown in FIG. 8K, the graphene layer 904 can line the lower sidewall 830a, the upper sidewall 830b, and the horizontal surface 830c. In some embodiments, the portion of the graphene layer 904 (e.g., the graphene layer 904 on a bottom surface of the lower cross-sectional profile 830c of the filling metal 830) that contacts with the filling metal 703 is thicker than the portion that does not contact with the filling metal 703 (see FIG. 8L). A portion of a top surface of the filling metal 703 non-overlapping with the filling metal 830 has no graphene formed thereon.

Reference is made to FIG. 8L. FIG. 8L illustrates a schematic cross-sectional view of a semiconductor structure corresponding to FIG. 8K. While FIG. 8L shows an embodiment of a semiconductor structure with a graphene layer as a diffusion barrier that that has a different thickness profile than in FIG. 8K. In addition, the present disclosure may repeat reference numerals and/or letters in the various examples. This repetition is for the purpose of simplicity and clarity and does not in itself dictate a relationship between the various embodiments and/or configurations discussed.

As shown in FIG. 8L, when using the HW-CVD process P1 to form the graphene layers 1004 and 1104 over the substrate 610, the graphene layer 1004 can have a thickness T1 on the source/drain contact 650 greater than a thickness T2 on the IMD layer 705, the ESL 700, and the graphene layer 904 can have a thickness T3 on the filling metal 703 greater than a thickness T4 on the IMD layers 802 and 806 and the ESLs 800 and 804. The reason for this difference can be the difference in surface properties and chemical interactions between the two types of the metal and the dielectric material. Specifically, metal can have higher surface energies compared to dielectric materials. This higher surface energy can promote the adsorption and nucleation of carbon atoms, leading to the formation of a thicker graphene layer. In addition, some metals, such as copper and nickel, are known to catalyze the formation of graphene by facilitating the decomposition of hydrocarbon precursors and the subsequent rearrangement of carbon atoms into the graphene lattice. This catalytic effect can result in a thicker graphene layer when formed on a metal substrate compared to a dielectric material, which does not exhibit such catalytic properties. Furthermore, metals generally have higher thermal conductivity compared to dielectric materials. This difference in thermal conductivity can result in more efficient heat dissipation in the metal substrate during the graphene formation process, potentially affecting the thickness and quality of the graphene layer formed. Moreover, the chemical interactions between the carbon atoms and the substrate can differ between metals and dielectric materials. These interactions can influence the nucleation, growth rate, and thickness of the graphene layer formed on the respective substrates. Therefore, the formation of a thicker graphene layer on metal substrates compared to dielectric materials using the above method can be attributed to differences in surface energy, catalytic effects, thermal conductivity, and chemical interactions between the substrates and carbon atoms.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides a method of forming graphene on dielectric materials at temperatures below 400 degrees Celsius. Other embodiments and variations are possible within the scope of the disclosure, as will be apparent to those skilled in the art. Specifically, a hot wire-chemical vapor deposition (HW-CVD) process is provided to perform a pyrolyzation on a carbon precursor. Subsequently, the pyrolyzed carbon precursor can be introduced to a dielectric material at a temperature lower than about 400° C. to form a graphene layer on the dielectric material, and the dielectric material is where the interconnects will be formed subsequently. In some embodiments, ammonia (NH₃) is introduced near the surface of the dielectric materials to react with the unpyrolyzed hydrocarbon precursors. This reaction ensures that the environment near the surface of the dielectric materials remains saturated with carbon, promoting the adsorption of carbon atoms onto the surface. After achieving the desired carbon atom coverage on the dielectric surface, the temperature on the dielectric materials decrease induces the adsorbed carbon atoms to arrange themselves into a two-dimensional honeycomb lattice structure, crystallizing into graphene on the surface of the dielectric materials.

This method enables the growth of graphene on dielectric materials at temperatures below 400 degrees Celsius, making it compatible with semiconductor BEOL processes and reducing the risk of thermal damage to the underlying structures. Unlike plasma-enhanced processes, this method does not involve plasma ion bombardment, minimizing the potential for damage to the dielectric material substrate and ensuring the integrity of the underlying structures. By controlling the reaction conditions and introducing specific gases, the method allows for the growth of high-quality graphene layers on dielectric materials, which can improve the performance of semiconductor devices in BEOL processes.

In some embodiments, a method includes loading a wafer having a dielectric layer thereon into a processing chamber; introducing a hydrocarbon precursor into the processing chamber; pyrolyzing a first portion of the hydrocarbon precursor; introducing the pyrolyzed first portion of the hydrocarbon precursor to the dielectric layer to form a graphene layer on the dielectric layer at a temperature lower than about 400° C. In some embodiments, the method further includes introducing an ammonia precursor into the processing chamber; reacting the ammonia precursor with an unpyrolyzed second portion of the hydrocarbon precursor to form a carbon source around the dielectric layer. In some embodiments, the ammonia precursor has a flow rate less than about 1% of a flow rate of the hydrocarbon precursor. In some embodiments, pyrolyzing the first portion of the hydrocarbon precursor is performing at a temperature in a range from about 2000° C. to 3000° C. In some embodiments, pyrolyzing the first portion of the hydrocarbon precursor is performed by a filament. In some embodiments, the filament is made of a tantalum-containing material. In some embodiments, the filament is spaced apart from the dielectric layer by a distance in a range from about 1 cm to 10 cm. In some embodiments, pyrolyzing the first portion of the hydrocarbon precursor comprises: providing a current in a range from about 4 A to 6 A to the filament. In some embodiments, introducing the pyrolyzed first portion of the hydrocarbon precursor to the dielectric layer to form the graphene layer comprises: heating the dielectric layer to a temperature in a range from about 300° C. to 400° C. In some embodiments, the dielectric layer comprises silicon oxide, silicon nitride, or combinations thereof.

In some embodiments, a method includes forming a transistor on a substrate; forming a source/drain contact on a source/drain region of the transistor; forming a dielectric layer over the source/drain contact; etching the dielectric layer to form an opening exposing the source/drain contact; growing a graphene layer over the dielectric layer and in the opening at a temperature in a range from about 300° C. to 400° C.; forming a filling metal in the opening of the dielectric layer. In some embodiments, growing the graphene layer comprises: introducing carbon atoms to the dielectric layer at a temperature in a range from about 300° C. to 400° C. In some embodiments, growing the graphene layer is performed under a pressure in a range from about 1 Torr to about 20 Torr. In some embodiments, a time-to-breakdown of the graphene layer in a time dependent dielectric breakdown (TDDB) measurement is greater than about 50 seconds. In some embodiments, the step of growing the graphene layer over the graphene layer further comprises growing the graphene layer on the source/drain contact. In some embodiments, the graphene layer has a thinner thickness on the dielectric layer than on the source/drain contact.

In some embodiments, a structure includes a semiconductor substrate, a gate structure, a source/drain structure, a contact, a dielectric layer, a first graphene layer. The gate structure is on the semiconductor substrate. The source/drain structure is on the semiconductor substrate. The contact over the source/drain structure. The dielectric layer over the contact and the gate structure. The first metal line extends through the dielectric layer to the contact. The first graphene layer wraps around the first metal line. The first graphene layer has a first portion between a sidewall of the first metal line and the dielectric layer and a second portion between the first metal line and the contact, and the second portion of the first graphene layer has a thicker thickness than the first portion of the first graphene layer. In some embodiments, the structure further includes a second metal line and a second graphene layer. The second metal line is over the first metal line and is a stepped sidewall structure having a lower sidewall, an upper sidewall laterally set back from the lower sidewall, and a horizontal surface connecting the lower sidewall to the upper sidewall. The second graphene layer wraps around the first metal line and has a first portion lining the lower sidewall, a second portion lining the upper sidewall, and a third portion lining the horizontal surface. In some embodiments, the second graphene layer further includes a fourth portion between the first and second metal lines, and the fourth portion of the second graphene layer has a thicker thickness than the first, second, and third portions of the second graphene layer. In some embodiments, a portion of a top surface of the first metal line non-overlapping with the second metal line has no graphene thereon.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
loading a wafer having a dielectric layer thereon into a processing chamber;
introducing a hydrocarbon precursor into the processing chamber;
pyrolyzing a first portion of the hydrocarbon precursor; and
introducing the pyrolyzed first portion of the hydrocarbon precursor to the dielectric layer to form a graphene layer on the dielectric layer at a temperature lower than about 400° C.

2. The method of claim 1, further comprising:
introducing an ammonia precursor into the processing chamber; and
reacting the ammonia precursor with an unpyrolyzed second portion of the hydrocarbon precursor to form a carbon source around the dielectric layer.

3. The method of claim 2, wherein the ammonia precursor has a flow rate less than about 1% of a flow rate of the hydrocarbon precursor.

4. The method of claim 1, wherein pyrolyzing the first portion of the hydrocarbon precursor is performing at a temperature in a range from about 2000° C. to 3000° C.

5. The method of claim 1, wherein pyrolyzing the first portion of the hydrocarbon precursor is performed by a filament.

6. The method of claim 5, wherein the filament is made of a tantalum-containing material.

7. The method of claim 5, wherein the filament is spaced apart from the dielectric layer by a distance in a range from about 1 cm to 10 cm.

8. The method of claim 5, wherein pyrolyzing the first portion of the hydrocarbon precursor comprises:
providing a current in a range from about 4 A to 6 A to the filament.

9. The method of claim 1, wherein introducing the pyrolyzed first portion of the hydrocarbon precursor to the dielectric layer to form the graphene layer comprises:
heating the dielectric layer to a temperature in a range from about 300° C. to 400° C.

10. The method of claim 1, wherein the dielectric layer comprises silicon oxide, silicon nitride, or combinations thereof.

11. A method, comprising:
forming a transistor on a substrate;
forming a source/drain contact on a source/drain region of the transistor;
forming a dielectric layer over the source/drain contact;
etching the dielectric layer to form an opening exposing the source/drain contact;
growing a graphene layer over the dielectric layer and in the opening at a temperature in a range from about 300° C. to 400° C.; and
forming a filling metal in the opening of the dielectric layer.

12. The method of claim 11, wherein growing the graphene layer comprises:
introducing carbon atoms to the dielectric layer at a temperature in a range from about 300° C. to 400° C.

13. The method of claim 11, wherein growing the graphene layer is performed under a pressure in a range from about 1 Torr to about 20 Torr.

14. The method of claim 11, wherein a time-to-breakdown of the graphene layer in time dependent dielectric breakdown (TDDB) measurement is greater than about 50 seconds.

15. The method of claim 11, wherein the step of growing the graphene layer over the graphene layer further comprises growing the graphene layer on the source/drain contact.

16. The method of claim 15, wherein the graphene layer has a thinner thickness on the dielectric layer than on the source/drain contact.

17. A structure, comprising:
a semiconductor substrate;
a gate structure on the semiconductor substrate;
a source/drain structure on the semiconductor substrate;
a contact over the source/drain structure;
a dielectric layer over the contact and the gate structure;
a first metal line extending through the dielectric layer to the contact; and
a first graphene layer wrapping around the first metal line, the first graphene layer having a first portion between a sidewall of the first metal line and the dielectric layer, and a second portion between the first metal line and the contact, the second portion of the first graphene layer having a thicker thickness than the first portion of the first graphene layer.

18. The structure of claim 17, further comprising:
a second metal line over the first metal line, the second metal line having a stepped sidewall structure having a lower sidewall, an upper sidewall laterally set back from the lower sidewall, and a horizontal surface connecting the lower sidewall to the upper sidewall; and
a second graphene layer wrapping around the first metal line, the second graphene layer comprising a first portion lining the lower sidewall, a second portion lining the upper sidewall, and a third portion lining the horizontal surface.

19. The structure of claim 18, wherein the second graphene layer further comprises a fourth portion between the first and second metal lines, and the fourth portion of the second graphene layer has a thicker thickness than the first, second, and third portions of the second graphene layer.

20. The structure of claim 18, wherein a portion of a top surface of the first metal line non-overlapping with the second metal line has no graphene thereon.
